(19) United States
(12) Patent Application Publication
(10) Pub. No.: US 2025/0185233 A1
(43) Pub. Date: Jun. 5, 2025

(54) SEMICONDUCTOR DEVICE

(71) Applicant: SAMSUNG ELECTRONICS CO., LTD., SUWON-SI (KR)

(72) Inventors: JOONGCHAN SHIN, Suwon-si (KR); Jinwoo Han, Suwon-si (KR); Taegyu Kang, Suwon-si (KR)

(21) Appl. No.: 18/884,517

(22) Filed: Sep. 13, 2024

(30) Foreign Application Priority Data
Dec. 4, 2023 (KR) 10-2023-0173429

(51) Int. Cl. H10B 12/00

(52) U.S. Cl. CPC H10B 12/482; H10B 12/315; H10B 12/50

(57) ABSTRACT

The present disclosure relates to a semiconductor device, and the semiconductor device according to an embodiment includes a substrate including a cell array region and a connection region, bit lines disposed on the substrate and extending along a first direction, a shield pattern disposed on the bit lines, word lines spaced apart from each other and disposed on the bit lines along the first direction and extending in a second direction that intersects the first direction and active patterns disposed between the word lines on the bit lines. The shield pattern includes line parts disposed between the bit lines and extending along the first direction, and a plate part disposed on the line parts and extending along the first direction and the second direction. A length of the line parts along the first direction is different from a length of the plate part along the first direction. A length of the bit lines along the first direction is longer than the length of the line parts along the first direction.

### CROSS-REFERENCE TO RELATED APPLICATION

This application claims priority under 35 U.S.C. § 119 to Korean Patent Application No. 10-2023-0173429, filed on Dec. 4, 2023 in the Korean Intellectual Property Office, the entire contents of which are herein incorporated by reference.

### 1. TECHNICAL FIELD

The present disclosure relates to a semiconductor device.

### 2. DISCUSSION OF THE RELATED ART

To meet the demand for superior performance and affordability from consumers, there's a growing need to enhance the integration of semiconductor memory devices. This is particularly crucial in the realm of semiconductor memory devices, as heightened integration directly impacts the product's pricing, making it a pivotal factor to address.

With two-dimensional or planar semiconductor memory devices, integration hinges primarily on the space occupied by each unit memory cell, making it heavily reliant on the precision of fine pattern formation technology. However, the cost associated with the equipment required for this refinement poses a challenge, resulting in limitations to the integration potential of 2D semiconductor memory devices despite ongoing advancements.

Accordingly, the semiconductor memory devices including a vertical channel transistor (VCT) whose channel extends in the vertical direction are being proposed.

### SUMMARY

A semiconductor device according to an embodiment includes a substrate including a cell array region and a connection region, bit lines disposed on the substrate and extending along a first direction, a shield pattern disposed on the bit lines, word lines spaced apart from each other and disposed on the bit lines along the first direction and extending in a second direction that intersects the first direction and active patterns disposed between the word lines on the bit lines. The shield pattern includes line parts disposed between the bit lines and extending along the first direction, and a plate part disposed on the line parts and extending along the first direction and the second direction. A length of the line parts along the first direction is different from a length of the plate part along the first direction. A length of the bit lines along the first direction is longer than the length of the line parts along the first direction.

A semiconductor device according to an embodiment includes a substrate including a cell array region, first periphery connection regions disposed adjacent to the cell array region along a first direction, and second periphery connection regions disposed adjacent to the cell array region and the first periphery connection regions along a second direction intersecting the first direction, bit lines disposed on the substrate and extending along the first direction, a shield pattern disposed on the bit lines, word lines spaced apart from each other and disposed on the bit lines along the first direction and extending along the second direction intersecting the first direction, active patterns disposed between the word lines, a back gate electrode disposed between the active patterns and extending along the second direction and a bit line insulation pattern disposed between adjacent bit lines in the first periphery connection regions. The shield pattern includes line parts disposed between the bit lines disposed adjacent to each other in the cell array region and extending along the first direction, a plate part disposed on the line parts and the bit line insulation pattern and extending along the first direction and the second direction. A length of the line parts along the first direction is shorter than a length of the plate part along the first direction. A length of the bit lines along the first direction is longer than the length of the line parts along the first direction. The end of the plate part of the shield pattern is disposed in the first periphery connection regions.

A semiconductor device according to an embodiment includes a substrate including a cell array region, first periphery connection regions disposed adjacent to the cell array region along a first direction, and second periphery connection regions disposed adjacent to the cell array region and the first periphery connection regions along a second direction intersecting the first direction, a peripheral circuit structure including peripheral circuits disposed on the substrate and a peripheral circuit insulating layer at least partially covering the peripheral circuits, bit lines disposed on the substrate and extending along the first direction, a shield pattern disposed on the bit lines, word lines spaced apart from each other and on the bit lines along the first direction and extending along the second direction intersecting the first direction, active patterns disposed between the word lines, a back gate electrode disposed between the active patterns and extending along the second direction, a bit line insulation pattern disposed between the bit lines disposed adjacent to each other in the first periphery connection regions and a plurality of bit line contact plugs connected to the bit lines disposed in the first periphery connection regions and overlapping the bit lines and the bit line insulation pattern. The shield pattern includes line parts disposed between the bit lines disposed adjacent to each other in the cell array region and extending along the first direction, and a plate part disposed on the line parts and the bit line insulation pattern and extending along the first direction and the second direction. A length of the line parts along the first direction is shorter than a length of the plate part along the first direction. A length of the bit lines along the first direction is longer than the length of the line parts along the first direction. The length of the bit lines along the first direction is the substantially same as the length of the plate part along the first direction.

### BRIEF DESCRIPTION OF THE DRAWINGS

FIG. 1 is a top plan view of a semiconductor device according to embodiments.

FIG. 2 is a partial perspective view of a semiconductor device according to an embodiment.

FIG. 3 is a partial perspective view showing a shield pattern of FIG. 2.

FIG. 4 is a partial top plan view of a semiconductor device according to an embodiment.

FIG. 5 is a partial top plan view showing a bit line, a shield pattern, a spacer insulating layer, a bit line insulation pattern, and a bit line contact plug of FIG. 4.

FIG. 6 is a cross-sectional view taken along a line A-A′ of FIG. 1.

FIG. 7 is a partial enlarged view of a region P of FIG. 6.

FIG. 8 is a cross-sectional view showing a cross-section taken along a line B-B′ and a line C-C′ of FIG. 1 and a cross-section of a second periphery connection region.

FIG. 9 is a cross-sectional view taken along a line D-D′ of FIG. 1.

FIG. 10 and FIG. 12 are partial layout views showing a bit line, shield pattern, a spacer insulating layer, a bit line insulation pattern, and a bit line contact plug of a semiconductor device according to some embodiments.

FIG. 11 is a cross-sectional view cut along a line D-D′ of FIG. 1 according to some embodiments.

FIG. 13, FIG. 14, and FIG. 19 are layout views of a semiconductor device according to some embodiments.

FIG. 15 and FIG. 20 are partial perspective views of a semiconductor device according to some embodiments.

FIG. 16 and FIG. 21 are partial layout views of a semiconductor device according to some embodiments.

FIG. 17 is a cross-sectional view cut along a line A-A′ in FIG. 13. according to some embodiments.

FIG. 18 is a cross-sectional view cut along a line D-D′ in FIG. 3. according to some embodiments.

FIG. 22 is a cross-sectional view cut along a line A-A′ in FIG. 19. according to some embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To the extent that an element has not been described in detail, it may be assumed that the element is at least similar to corresponding elements that have been described in previous figures.

The size and thickness of the configurations are optionally shown in the drawings for convenience of description, and the present disclosure is not necessarily limited to the drawings.

It will be understood that when an element such as a layer, film, region, or substrate is referred to as being “on” another element, it can be directly on the other element, or intervening elements may also be present. In contrast, when an element is referred to as being “directly on” another element, there are no intervening elements present. Further, in the specification, the word “on” or “above” means positioned on or below the object portion and does not necessarily mean positioned on the upper side of the object portion based on a gravitational direction.

Further, in the specification, the phrase “on a plane” means viewing the object portion from the top, and the phrase “on a cross-section” means viewing a cross-section of which the object portion is vertically cut from the side.

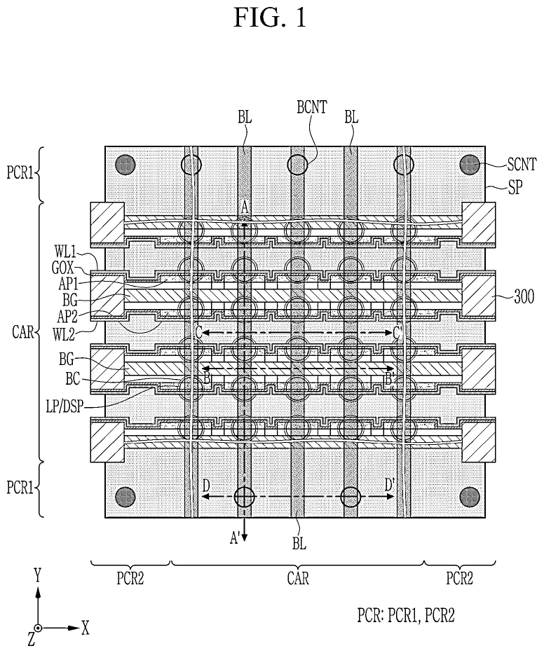

Hereinafter, a semiconductor device according to an embodiment is described with reference to FIG. 1 to FIG. 9.

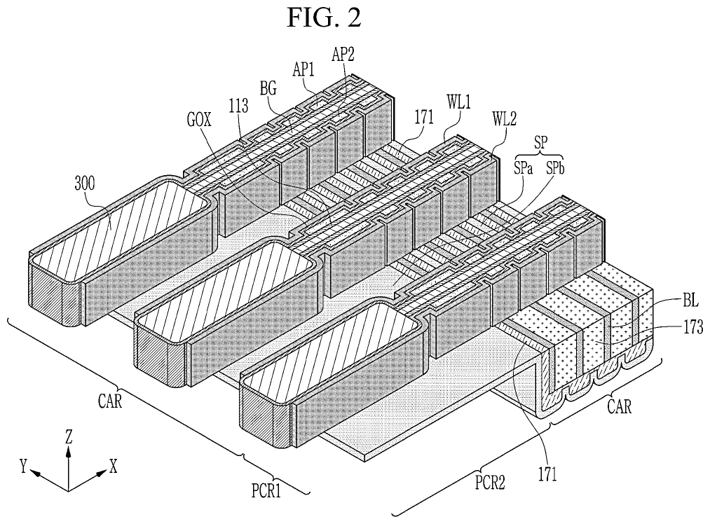

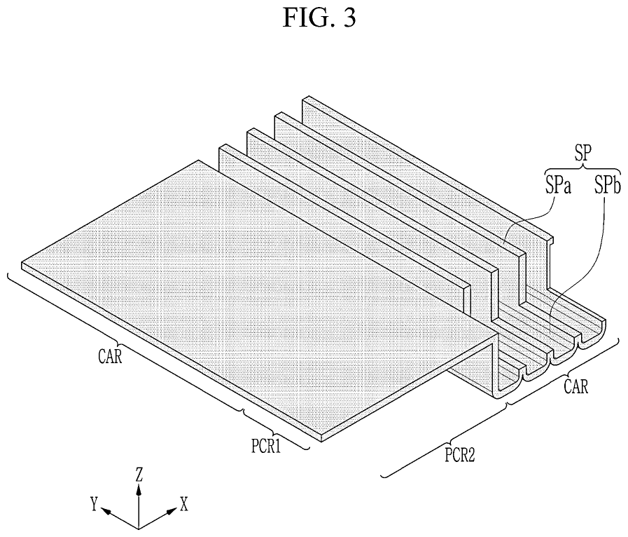

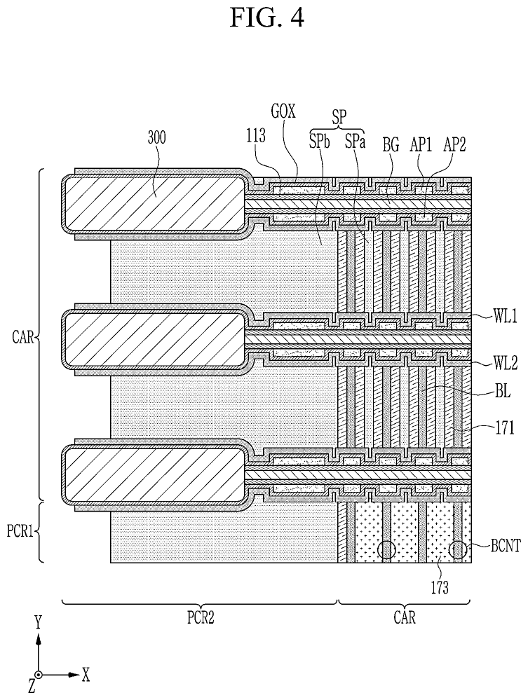

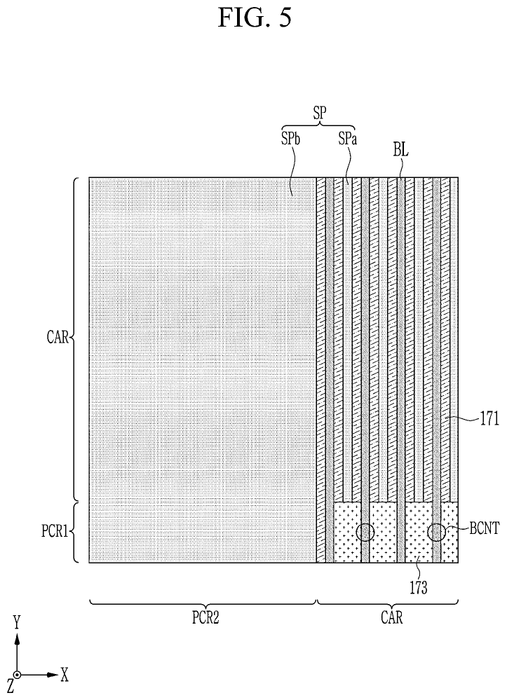

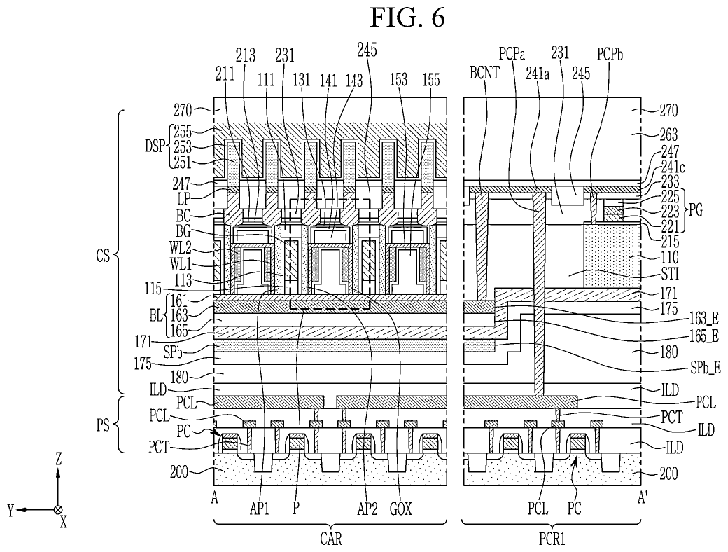

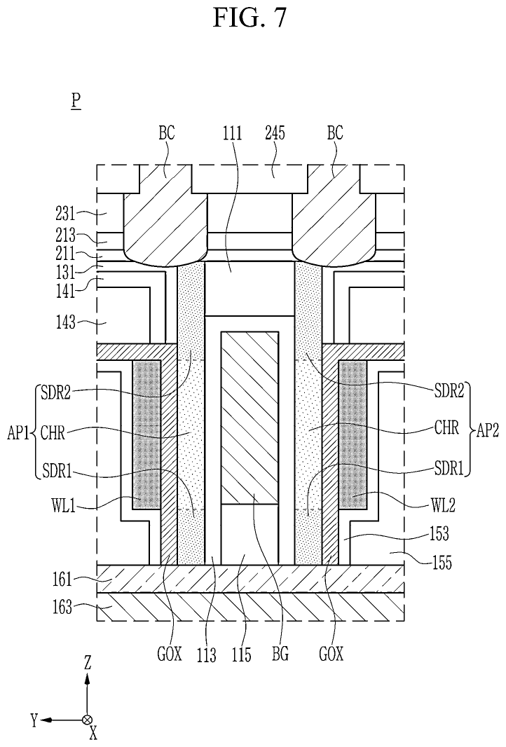

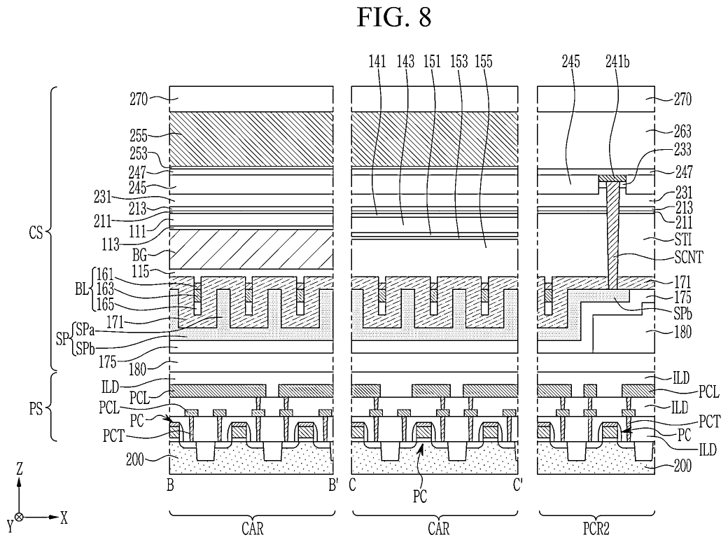

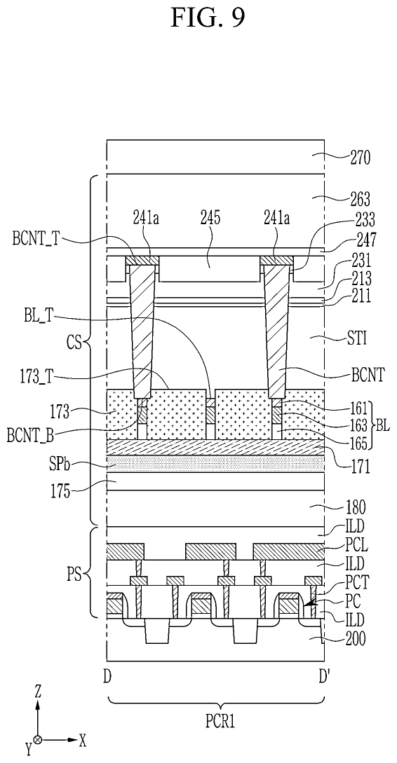

FIG. 1 is a top plan view of a semiconductor device according to embodiments. FIG. 2 is a partial perspective view of a semiconductor device according to an embodiment. FIG. 3 is a partial perspective view showing a shield pattern of FIG. 2. FIG. 4 is a partial top plan view of a semiconductor device according to an embodiment. FIG. 5 is a partial top plan view showing a bit line, a shield pattern, a spacer insulating layer, a bit line insulation pattern, and a bit line contact plug of FIG. 4. FIG. 6 is a cross-sectional view taken along a line A-A′ of FIG. 1. FIG. 7 is a partial enlarged view of a region P of FIG. 6. FIG. 8 is a cross-sectional view showing a cross-section taken along a line B-B′ and a line C-C′ of FIG. 1 and a cross-section of a second periphery connection region. FIG. 9 is a cross-sectional view taken along a line D-D′ of FIG. 1.

Semiconductor devices according to embodiments of the present disclosure may include memory cells such as a vertical channel transistor (VCT).

A semiconductor device according to an embodiment may include a substrate 200, a peripheral circuit structure PS, and a cell array structure CS connected to the peripheral circuit structure PS.

The substrate 200 may include a cell array region CAR and a periphery connection region PCR defined adjacent to the cell array region CAR. For example, the periphery connection region PCR may at least partially surround the cell array region CAR. The periphery connection region PCR may include first and second periphery connection regions PCR1 and PCR2 positioned adjacent to the cell array region CAR. For example, the first and second periphery connection regions PCR1 and PCR2 may at least partially surround the cell array region CAR. For example, the cell array region CAR may be positioned between the first periphery connection regions PCR1 along the second direction Y or the cell array region CAR may be positioned between the second periphery connection regions PCR2 along the first direction X. The first periphery connection region PCR1 may be positioned between the second periphery connection regions PCR2 along the first direction X. For example, the first periphery connection region PCR1 may be positioned on one side and the other side of the cell array region CAR along the second direction Y, and the second periphery connection region PCR2 may be positioned on one side and the other side of the cell array region CAR along the second direction Y. For example, the cell array region CAR may be disposed between the first periphery connection regions PCR1 along the second direction Y and disposed between the second periphery connection regions PCR2 along the first direction X. However, the arrangement relationship of the cell array region CAR and the periphery connection region PCR is not necessarily limited to this and may be changed in various ways.

In the cell array region CAR of the substrate 200, first and second active patterns AP1 and AP2, bit lines BL, first and second word lines WL1 and WL2, a shield pattern SP, landing pads LP, data storing patterns DSP, and the like may be positioned. In the periphery connection region PCR, a separation insulation pattern 300, a bit line contact plug BCNT, and a shield pattern contact plug SCNT, and the like may be positioned.

The substrate 200 may include a monocrystalline silicon substrate or other materials, such as silicon germanium, indium antimonide, a lead telluride compound, indium arsenic, indium phosphide, gallium arsenic, or gallium antimonide, but is not necessarily limited thereto.

The peripheral circuit structure PS may be positioned on the substrate 200. The peripheral circuit structure PS may be positioned between the substrate 200 and the cell array structure CS. The peripheral circuit structure PS may be positioned across the cell array region CAR and the periphery connection region PCR of the substrate 200. For example, a part of the peripheral circuit structure PS may be positioned in the cell array region CAR of the substrate 200, and the remaining part may be positioned in the periphery connection region PCR.

The peripheral circuit structure PS may be placed between the substrate 200 and a planarization insulating layer 180 of the cell array structure CS. The peripheral circuit structure PS may include a core and peripheral circuits PC positioned on the substrate 200, peripheral circuit insulating layers ILD covering the core and the peripheral circuits PC which are disposed between the substrate 200 and the planarization insulating layer 180, and periphery metal structures PCT and PCL disposed within the peripheral circuit insulating layers ILD.

The core and peripheral circuits PC may include row and column decoders, sense amplifiers, control logics, etc. For example, the core and peripheral circuits PC may include NMOS and PMOS transistors integrated on the substrate 200. However, it is not necessarily limited thereto, and the type of the transistor of the peripheral circuits PC positioned on the substrate 200 of the cell array region CAR may vary depending on the design arrangement of the semiconductor device.

The peripheral circuit insulating layers ILD may cover the core and peripheral circuits PC and the periphery metal structures PCL and PCT. The peripheral circuit insulating layers ILD may include multi-layered insulating layers.

The peripheral circuit insulating layers ILD may include an insulating material. For example, it may include silicon oxide, silicon nitride, silicon oxynitride, and/or low dielectric material.

The peripheral metal structures PCT and PCL may include at least two metal patterns PCL and metal plugs PCT which are connected to the metal patterns PCL.

The cell array structure CS may include, as described above, may include the memory cells including the vertical channel transistor (VCT). Specifically, the cell array structure CS may include the vertical channel transistor (VCT) as a cell transistor of each memory cell and a capacitor as a data storage element of each memory cell. The vertical channel transistor may refer to a structure in which the channel length extends in a vertical direction with respect to the upper surface of the substrate 200.

The cell array structure CS may include bit lines BL, a spacer insulating layer 171, a bit line insulation pattern 173, a shield pattern SP, first and second active patterns AP1 and AP2, first and second word lines WL1 and WL2, back gate electrodes BG, a data storing pattern DSP, bit line contact plugs BCNT, and shield pattern contact plugs SCNT.

The bit lines BL of the cell array structure CS may be positioned adjacent to the peripheral circuit structure PS. Accordingly, since the bit lines BL are positioned adjacent to the peripheral circuit structure PS, the electrical connection path between the bit lines BL, and the core and peripheral circuits PC may be reduced.

The plurality of bit lines BL may be spaced apart from each other along the first direction X on the substrate 200. The bit lines BL may extend parallel to each other along the second direction Y intersecting the first direction X. For example, the bit lines BL may be extended along the second direction Y from the cell array region CAR toward the first periphery connection regions PCR1.

Accordingly, a portion of each bit lines BL may be positioned in the cell array region CAR, and the remaining portion of each bit lines BL may be positioned in the first periphery connection regions PCR1. For example, an end of each bit lines BL may be positioned in the first periphery connection region PCR1 and an opposite end of each bit lines BL may be positioned in the cell array region CAR along the second direction Y, respectively.

Each of the bit lines BL may include a polysilicon layer 161, a metal layer 163, and a bit line hard mask layer 165, that are sequentially stacked on top of each other. For example, the metal layer 163 may be interposed between the polysilicon layer 161 and the bit line hard mask layer 165.

The polysilicon layer 161 may include an impurity-doped polysilicon, and the metal layer 163 may include a conductive metal nitride (e.g., titanium nitride, tantalum nitride, etc.) and a metal (e.g., tungsten, titanium, tantalum, etc.). The metal layer 163 may include a metal silicide such as titanium silicide, cobalt silicide, or nickel silicide. The bit line hard mask layer 165 may include an insulating material such as silicon nitride or silicon oxynitride

However, the materials included in the polysilicon layer 161, the metal layer 163, and the bit line hard mask layer 165 are not necessarily limited thereto and may be changed in various ways.

In some embodiments, the bit lines BL may include two-dimensional or three-dimensional materials, such as graphene of a carbon-based two-dimensional material, a carbon nanotube of a three-dimensional material, or combinations thereof.

In FIG. 6, it is shown that the polysilicon layer 161 of the bit lines BL is not positioned in the first periphery connection region PCR1, but it is not necessarily limited to this, and the arrangement of the polysilicon layer 161 may be changed in various ways. For example, the polysilicon layer 161 of the bit lines BL may extend toward the first periphery connection region PCR1.

A bit line insulation pattern 173 may be positioned in a portion of the region between the adjacent bit lines BL. For instance, bit line insulation pattern 173 may be disposed in the first periphery connection region PCR1, running along the second direction Y, which aligns with the elongation of the bit lines BL. For example, the bit line insulation pattern 173 may be disposed between adjacent bit lines BL positioned within the first periphery connection regions PCR1. The bit line insulation pattern 173 may have a rectangle shape on a plane with a short axis along the first direction X and a long axis along the second direction Y. However, the planar shape of the bit line insulation pattern 173 is not necessarily limited thereto and may be changed in various ways.

Both side surfaces of the bit line insulation pattern 173 may be in direct contact with side surfaces of the adjacent bit lines BL.

The bit line insulation pattern 173 may have a first surface and a second surface facing each other along the second direction Y. For example, the first surface of the bit line insulation pattern 173 may be a surface adjacent to the cell array region CAR, and the second surface may be a surface positioned far from the cell array region CAR.

The first surface of bit line insulation pattern 173 may be positioned at the border of the cell array region CAR and the first periphery connection region PCR1. For example, the first surface of the bit line insulation pattern 173 may be aligned with a border substantially corresponds to the border of the cell array region CAR and the first periphery connection region PCR1. However, the arrangement of the bit line insulation pattern 173 is not necessarily limited thereto and may be changed in various ways. For example, the bit line insulation pattern 173 may extend from the first periphery connection region PCR1 towards the cell array region CAR along the second direction Y, which is the elongation direction of the bit lines BL. For example, a part of bit line insulation pattern 173 may be positioned in the first periphery connection region PCR1, and the remaining part may be positioned in the cell array region CAR.

As shown in FIG. 9, the upper surface 173_T of the bit line insulation pattern 173 may be positioned at a higher level than the upper surface BL_T of the bit lines BL. For example, the length of the bit line insulation pattern 173 along the third direction Z may be longer than the length Z of the bit lines BL along the third direction. For example, the upper surface 173_T of the bit line insulation pattern 173 may be positioned at a higher level than the upper surface of the polysilicon layer 161 of the bit lines BL. However, the arrangement relationship between the upper surface 173_T of the bit line insulation pattern 173 and the upper surface BL_T of the bit lines BL is not necessarily limited thereto and may be changed in various ways. For example, the upper surface 173_T of the bit line insulation pattern 173 may be positioned at a lower level than the upper surface BL_T of the bit lines BL, or may be positioned at a level substantially equivalent to the upper surface BL_T of the bit lines BL.

The bit line insulation pattern 173 may include an insulating material. For example, the bit line insulation pattern 173 may include at least one of silicon oxide, silicon nitride, silicon oxynitride, a low dielectric constant (low-k) material such as Silicon Oxycarbonitride (SiOCN), Silicon Oxycarbide (SiOC), Silicon Boron Nitride (SiBN), Silicon Boron Carbon Nitride (SiBCN), Silicon Boron Carbon Oxynitride (SiBCON), or a combination thereof. However, the insulating material included in the bit line insulation pattern 173 is not necessarily limited thereto and may be changed in various ways.

The bit line insulation pattern 173 according to an embodiment includes a single layer, but is not necessarily limited to thereto. For example, the bit line insulation pattern 173 may include two or more multiple layers.

The spacer insulating layer 171 may have a substantially uniform thickness and conformally disposed below the bit lines BL. The spacer insulating layer 171 may at least partially cover both surfaces and an upper surface BL_T of the bit lines BL. The spacer insulating layer 171 may define each gap region between the bit lines BL. The gap regions of the spacer insulating layer 171 may extend parallel to the bit lines BL along the second direction Y.

The gap region of the spacer insulating layer 171 defined between the bit lines BL adjacent to each other may extend and reach the border of the cell array region CAR and the first periphery connection region PCR1 along the second direction Y, which is substantially the same as the elongation direction of the bit lines BL. For example, the gap region and the spacer insulating layer 171 that defines the gap region may be extended along the second direction Y, which is the elongation direction of the bit lines BL and reach the first surface of the bit line insulation pattern 173 positioned in the first periphery connection region PCR1. For example, the gap region and the spacer insulating layer 171 that defines the gap region may be positioned in the cell array region CAR, but not in the first periphery connection regions PCR1.

Accordingly, the gap region and the spacer insulating layer 171 that defines the gap region may be in contact with the first surface of the bit line insulation pattern 173 positioned in the first periphery connection region PCR1. However, the arrangement of the gap region and the spacer insulating layer 171 that defines the gap region are not necessarily limited to this and may be changed in various ways. For example, the gap region and the spacer insulating layer 171 that defines the gap region may extend towards the first periphery connection region PCR1 along the second direction Y, which is substantially the same as the elongation direction of the bit lines BL. For example, the gap region and a part of the spacer insulating layer 171 that defines the gap region may be positioned in the cell array region CAR and the remaining part may be positioned in the first periphery connection region PCR1. For example, the end of the spacer insulating layer 171, which defines the gap region, may be positioned in the first periphery connection region PCR1.

Additionally, the spacer insulating layer 171, which does not define the gap region, may at least partially cover the side of the bit lines BL that positions the boundary between the cell array region CAR and the second periphery connection region PCR2. The spacer insulating layer 171, which does not define the gap region may be positioned between a shield pattern SP to be described later and the bit lines BL in the first periphery connection regions PCR1 and between the shield pattern SP and the bit line insulation pattern 173, and cover the bit lines BL and the bit line insulation pattern 173. For example, the spacer insulating layer 171 positioned in the first periphery connection regions PCR1 may cover the bottom surface and the end of the bit lines BL and the bottom surface and the end of the bit line insulation pattern 173.

This may be due to the formation of the spacer insulating layer 171 after the bit line insulation pattern 173 is formed between the adjacent bit lines BL positioned in the first periphery connection regions PCR1. For example, as the bit line insulation pattern 173 is formed first in the first periphery connection region PCR1, the arrangement shape of the spacer insulating layer 171 formed between the adjacent bit lines BL positioned in the cell array region CAR may be different from the arrangement shape of the spacer insulating layer 171 formed in the first periphery connection region PCR1.

The spacer insulating layer 171 may include an insulating material. For example, it may include a silicon oxide layer, a silicon nitride layer, a silicon oxynitride layer, and/or a low dielectric layer. However, the material included in the spacer insulating layer 171 is not necessarily limited thereto and may be changed in various ways.

The shield pattern SP may be positioned on the spacer insulating layer 171. The shield pattern SP may include line parts SPa which is respectively positioned between the adjacent bit lines BL and a plate part SPb that connects the line parts SPa.

For example, the line parts SPa of the shield pattern SP may be positioned between the adjacent bit lines BL. The line parts SPa of the shield pattern SP may be positioned within the gap regions defined in the spacer insulating layer 171 between the bit lines BL. For example, the line parts SPa of the shield pattern SP and the sides of the bit lines BL may be spaced apart in the first direction X, with the spacer insulating layer 171 in between.

According to an embodiment of the present invention, the line parts Spa of the shield pattern SP, like the gap region of the spacer insulating layer 171, may extend towards the boundary of the cell array region CAR and the first periphery connection region PCR1 from the cell array region CAR along the second direction Y that is the same as the elongation direction of the bit lines BL. For example, the line parts SPa of the shield pattern SP extend towards the first surface of the bit line insulation pattern 173 located in the first periphery connection region PCR1, and the end of the line parts SPa of the shield pattern SP may be in direct contact with the first surface of the bit line insulation pattern 173. For example, the line parts SPa of the shield pattern SP may be positioned in the cell array region CAR, but not in the first periphery connection regions PCR1.

Accordingly, between the bit lines BL adjacent to each other positioned in the cell array region CAR, the spacer insulating layer 171 and the line parts Spa of the shield pattern SP may be sequentially positioned, and the bit line insulation pattern 173 may be positioned between the bit lines BL adjacent to each other positioned in the first periphery connection regions PCR1. However, the arrangement of the line parts SPa of the shield pattern SP is not necessarily limited to this and may be changed in various ways. For example, since the line parts SPa of the shield pattern SP are positioned within the gap region of the spacer insulating layer 171, the arrangement of the line parts SPa of the shield pattern SP may vary depending on the arrangement of the gap region defined by the spacer insulating layer 171.

For example, the line parts SPa of the shield pattern SP may extend towards the first periphery connection region PCR1 along the second direction Y, which is the elongation direction of the bit lines BL. For example, a part of each line part SPa of the shield pattern SP may be positioned in the cell array region CAR, and the remaining part of each line part SPa of the shield pattern SP may be positioned in the first periphery connection region PCR1. For example, the ends of the line parts SPa of the shield pattern SP may be positioned in the first periphery connection region PCR1.

In an embodiment of the present invention, as the line parts SPa of the shield pattern SP are positioned within the gap region of the spacer insulating layer 171 defined between the bit lines BL adjacent to each other, the length of the line parts SPa of the shield pattern SP along the second direction Y may be substantially equivalent to the length of the gap region of the spacer insulating layer 171 along the second direction Y.

Unlike the bit lines BL positioned in the cell array region CAR and the first periphery connection region PCR1, because the line parts SPa of the positioned shield pattern SP are only positioned in the first periphery connection regions PCR1, the length of the line parts SPa of the shield pattern SP along the second direction Y and the length of the bit lines BL along the second direction Y may be different. For example, the length of the line parts SPa of the shield pattern SP along the second direction Y may be shorter than the length of the bit lines BL along the second direction Y.

In an embodiment of the present invention, the length of the bit lines BL along the second direction Y may be substantially equivalent to the sum of the length of the line parts SPa of the shield pattern SP along the second direction Y and the length of the bit line insulation pattern 173 along the second direction Y.

This may be a result of sequentially forming the spacer insulating layer 171 that delineates the gap region and the line parts SPa of the shield pattern SP in the remaining region between the adjacent bit lines BL after forming the bit line insulation pattern 173 in some regions between the adjacent bit lines BL.

The line parts SPa of the shield pattern SP positioned between the adjacent bit lines BL in the cell array region CAR may reduce the coupling capacitance caused by the mutual interference between the bit lines BL positioned adjacent to each other.

The plate part SPb of the shield pattern SP may be connected to the line parts SPa and may be integrated with the line part SPa. For example, the plate part SPb of the shield pattern SP may be placed on line parts SPa and connect the line parts SPa placed between the adjacent bit lines BL to each other. The line parts SPa of the shield pattern SP may extend from the plate part SPb of the shield pattern SP along the third direction Z, which is a vertical direction to the substrate 200, and may be positioned between the adjacent bit lines BL. The plate part SPb of the shield pattern SP may overlap with the bit lines BL along the third direction Z, which is a vertical direction to the substrate 200, in the cell array region CAR. However, the configuration of the line parts SPa and plate part SPb of the shield pattern SP is not necessarily limited thereto. In some embodiments, the line part SPa and plate part SPb of the shield pattern SP may be made of separate configurations.

FIG. 8 shows that the height of the bit lines BL along the third direction Z is higher than the height of the line part SPa of the shield pattern SP along the third direction Z. But it is not necessarily limited thereto and the height of the bit lines BL along the third direction Z may be substantially equivalent to the height of the line part SPa of the shield pattern SP along the third direction Z.

The plate part SPb of the shield pattern SP and the bottom surface of the bit lines BL may be spaced apart from each other along the third direction Z with the spacer insulating layer 171 in between.

The plate part SPb of the shield pattern SP may extend along the second direction Y from the cell array region CAR towards the first periphery connection regions PCR1. The plate part SPb of the shield pattern SP may extend along the first direction X from the cell array region CAR towards the second periphery connection region PCR2. For example, the end point in the second direction Y and the end point in the first direction X of the plate part SPb of the shield pattern SP may be positioned in the first periphery connection region PCR1 and the second periphery connection region PCR2, respectively.

For example, the length of the plate part SPb of the shield pattern SP along the second direction Y may be different from the length of the line parts SPa of the shield pattern SP along the second direction Y. For example, as shown in FIG. 4, the length of the plate part SPb of the shield pattern SP along the second direction Y may be longer than the length of the line parts SPa of the shield pattern SP along the second direction Y. For example, unlike the line parts Spa of the shield pattern SP, which are positioned only in the cell array region CAR, the plate part SPb of the shield pattern SP may be positioned across the cell array region CAR and the first periphery connection region PCR1.

Additionally, in an embodiment of the present invention, the length of the plate part SPb of the shield pattern SP along the second direction Y may be substantially equivalent to the length of the bit lines BL along the second direction Y. However, the relationship of the length of the plate part SPb of the shield pattern SP along the second direction Y and the length of the bit lines BL along the second direction Y is not necessarily limited to this and may be changed in various ways. The detailed description thereof is provided later.

Accordingly, as shown in FIG. 6, the end SPb_E of the plate part SPb of the shield pattern SP, the end 163_E of the metal layer 163 among the bit lines BL, and the end 165_E of the bit line hard mask layer 165 may be positioned in the first periphery connection region PCR1 and aligned on the same boundary as each other. However, it is not necessarily limited thereto. In some embodiments, when the polysilicon layer 161 of the bit lines BL is further extended towards the first periphery connection region PCR1, the end of the polysilicon layer 161 may be aligned with the boundary which is substantially equivalent to the end SPb_E of the plate part SPb of the shield pattern SP.

The length of the plate part SPb of the shield pattern SP along the first direction X may be shorter than the length of the first and second word lines WL1 and WL2 along the first direction X. For example, the ends of the first and second word lines WL1 and WL2 may be positioned further apart from the cell array region CAR into one side and the other side in the first direction X than the ends of the plate part SPb of the shield pattern SP. For example, each part of the first and second word lines WL1 and WL2 positioned in the second periphery connection regions PCR2 may overlap the plate part SPb of the shield pattern SP along the third direction Z which is the direction vertical to the substrate 200, and the remaining part of each of the first and second word lines WL1 and WL2 might not overlap the plate part SPb of the shield pattern SP along the third direction Z. However, the arrangement relationship between the plate part SPb of the shield pattern SP and the first and second word lines WL1 and WL2 is not necessarily limited thereto and may be changed in various ways. The detailed description thereof is provided later.

The shield pattern SP may include a conductive material. For example, it may include metal materials such as tungsten (W), titanium (Ti), nickel (Ni), or cobalt (Co). As another example, the shield pattern SP may include a conductive two-dimensional 2D material such as graphene.

FIG. 2 to FIG. 9 only illustrate the first periphery connection region PCR1 positioned at one side of the cell array region CAR along the second direction Y and the second periphery connection region PCR2 positioned at one side along the first direction X. FIG. 2 to FIG. 9 do not show the first periphery connection region PCR1 positioned at the other side of the cell array region CAR along the second direction Y and the second periphery connection region PCR2 positioned at the other side in the first direction X, nor show the second periphery connection region PCR2 disposed on the opposite side along the first direction X. Instead, FIG. 2 to FIG. 9 illustrate arrangement within the first periphery connection region PCR1 on one side of the cell array region CAR along the second direction Y and the second periphery connection region PCR2 on one side along the first direction X. The arrangement between these configurations may be assumed to be substantially the same to those found in the first periphery connection region PCR1 on the opposite side of the cell array region CAR along the second direction Y, and also in the second periphery connection region PCR2 on the opposite side along the first direction X.

The semiconductor device according to an embodiment of the present invention may further include a capping insulating layer 175 and a planarization insulating layer 180 positioned between the peripheral circuit structure PS and the capping insulating layer 175.

The capping insulating layer 175 may have the substantially uniform thickness and at least partially cover the shield pattern SP.

As shown in FIG. 6, in the first periphery connection region PCR1, the capping insulating layer 175 may at least partially cover the end of the plate part SPb of the shield pattern SP and be in direct contact with the spacer insulating layer 171.

The capping insulating layer 175 may include an insulating material. For example, the capping insulating layer 175 may include a silicon oxide layer, a silicon nitride layer, a silicon oxynitride layer, and/or a low dielectric layer.

The planarization insulating layer 180 may at least partially cover the capping insulating layer 175 and planarize the lower region of the cell array structure CS which is in contact with the peripheral circuit structure PS. The thickness of the planarization insulating layer 180 may be different in the cell array region CAR and the first and second periphery connection regions PCR1 and PCR2. The planarization insulating layer 180 may be, for example, any one of insulating materials and a silicon oxide layer formed using Spin on Glass (SOG) technology.

The first active patterns AP1 and the second active patterns AP2 may be positioned on the bit lines BL. The first active patterns AP1 and the second active patterns AP2 may be positioned in alternating order along the second direction Y. For example, the first active patterns AP1 may be interposed between the second active patterns AP2.

The first active patterns AP1 may be separated from each other along the first direction X.

The first active patterns AP1 may be spaced out from each other at a regular interval. The second active patterns AP2 may be spaced apart from each other along the first direction X.

The second active patterns AP2 may be spaced out at a regular interval. The first and second active patterns AP1 and AP2 may be arranged two-dimensionally along the first direction X and the second direction Y that intersect each other. The first active pattern AP1 and the second active pattern AP2 may each be made of a monocrystalline semiconductor material. For example, the first active pattern AP1 and the second active pattern AP2 may each include a monocrystalline silicon.

The first active pattern AP1 and the second active pattern AP2 may each have a length measured along the first direction X, a width measured along the second direction Y, and a height measured along the third direction Z. The first active pattern AP1 and the second active pattern AP2 may each have a substantially uniform width. For example, each of the first active pattern AP1 and the second active pattern AP2 may have the substantially equivalent widths on the first and second surfaces facing each other along the third direction Z, which is the vertical direction. Additionally, the width of the first active pattern AP1 may be the same as the width of the second active pattern AP2.

Referring to FIG. 6 and FIG. 7, each of the first and second active patterns AP1 and AP2 may have the first surface and the second surface facing to each other along the direction vertical to the first and second directions X and Y. For example, the first surfaces of the first and second active patterns AP1 and AP2 may be in contact with the polysilicon layer 161 of the bit lines BL. However, unlike illustrated in FIG. 6 and FIG. 7, in some embodiments, when the polysilicon layer 161 is omitted, the first and second active patterns AP1 and AP2 may be in contact with the metal layer 163.

The first and second active patterns AP1 and AP2 each may include a first side and a second side opposite to each other along the second direction Y. The first side of the first active pattern AP1 may be disposed adjacent to the first word line WL1, and the second side of the second active pattern AP2 may be disposed adjacent to the second word line WL2.

As shown in FIG. 7, the first and second active patterns AP1 and AP2 each include a first dopant region SDR1 adjacent to the bit lines BL, a second dopant region SDR2 adjacent to the contact patterns BC, and a channel region CHR between the first and second dopant regions SDR1 and SDR2. For example, the second dopant region SDR2 may be disposed on the channel region CHR which is disposed on the first dopant region SDR1. The first and second dopant regions SDR1 and SDR2 are regions where a dopant is doped within the first and second active patterns AP1 and AP2, and the dopant concentration in the first and second dopant regions SDR1 and SDR2 may be greater than the dopant concentration in the channel region CHR. However, unlike shown in FIG. 7, in some embodiments, each of the first active pattern AP1 and the second active pattern AP2 might not include at least one of the first dopant region SDR1 and the second dopant region SDR2.

The channel regions CHR of the first and second active patterns AP1 and AP2 may be controlled by the first and second word lines WL1 and WL2 and the back gate electrodes BG during an operation of the semiconductor device. Since the first and second active patterns AP1 and AP2 are made of a monocrystalline semiconductor material, a leakage current characteristic of the semiconductor memory device may be improved.

The back gate electrodes BG may be positioned between the first active pattern AP1 and the second active pattern AP2, which are adjacent to each other along the second direction Y. For example, the first active pattern AP1 may be positioned on one side of each back gate electrode BG, and the second active pattern AP2 may be positioned on the other side of each back gate electrode BG. The height of back gate electrode BG along the third direction Z may be smaller than the height of the first and second active patterns AP1 and AP2 along the third direction Z. The back gate electrode BG may include a conductive material. For example, the back gate electrode BG may include at least one of doped polysilicon, conductive metal nitride, conductive metal silicon nitride, metal carbon nitride, conductive metal silicide, conductive metal oxide, two-dimensional material, and metal.

The back gate electrodes BG may be applied with a negative voltage when the semiconductor device operates and may increase the threshold voltage of the vertical channel transistor. This reduces the degradation of the leakage current characteristic caused by the decrease in threshold voltage due to transistor miniaturization.

Specifically, referring to FIG. 6 and FIG. 7, the back gate electrode BG may include a first surface adjacent to the bit lines BL and a second surface adjacent to the contact patterns BC. The first and second surfaces of the back gate electrode BG may be positioned at different levels from the first and second surfaces of the first and second active patterns AP1 and AP2.

The semiconductor device according to an embodiment of the present invention may further include a back gate separation pattern 111, a back gate insulation pattern 113, and a back gate capping pattern 115.

The back gate separation pattern 111 may be positioned between the first and second active patterns AP1 and AP2, which are adjacent to each other along the second direction Y. For example, the back gate separation pattern 111 may be positioned between the second dopant regions SDR2 of the first and second active patterns AP1 and AP2. The back gate separation pattern 111 may extend parallel to the back gate electrodes BG along the first direction X.

The back gate separation pattern 111 may include an insulating material. For example, it may include any one of silicon oxide, silicon oxynitride, silicon nitride, or a combination thereof.

The back gate insulation pattern 113 may be positioned between the back gate electrode BG and the first active pattern AP1 along the second direction Y. The back gate insulation pattern 113 may be positioned between the back gate electrode BG and the second active pattern AP2 along the second direction Y. The back gate separation pattern 111, the first active pattern AP1, the second active pattern AP2, the back electrode BG and the back gate capping pattern 115 may at least partially surround the back gate insulation pattern 113.

The back gate insulation pattern 113 may include vertical parts at least partially covering both sides of the back gate electrode BG and a horizontal part connecting the vertical parts. The horizontal part of the back gate insulation pattern 113 may be closer to the contact patterns BC than the bit lines BL and at least partially cover the second surface of the back gate electrode BG.

The back gate insulation pattern 113 may include an insulating material. For example, the back gate insulation pattern 113 may include any one of silicon oxide, silicon oxynitride, a high dielectric constant material having a dielectric constant higher than silicon oxide, or a combination thereof.

The back gate capping pattern 115 may be positioned between the bit lines BL and the back gate electrode BG along the third direction Z. The back gate capping pattern 115 may be positioned between the first active pattern AP1 and the second active pattern AP2 along the second direction Y. The back gate capping pattern 115 may be extended parallel to the bit lines BL and the back gate electrode BG along the first direction X.

The bottom surface of the back gate capping pattern 115 may be in direct contact with the polysilicon layer 161 of the bit lines BL. The back gate capping pattern 115 may be positioned between the vertical parts of the back gate insulation pattern 113. For example, the back gate insulation pattern 113, the back gate electrode BG and the polysilicon layer 161 may at least partially surround the back gate capping pattern 115. The thickness of the back gate capping pattern 115 between the bit lines BL may be different from the thickness of the back gate capping pattern 115 on the bit lines BL.

The back gate capping pattern 115 may include an insulating material. For example, the back gate capping pattern 115 may include any one of silicon oxide, silicon oxynitride, silicon nitride, or a combination thereof.

The first word line WL1 and the second word line WL2 may be positioned on the bit lines BL.

Each of the first word line WL1 and the second word line WL2 may be extended along the first direction X. The first word line WL1 and the second word line WL2 may be arranged in alternating order along the second direction Y.

The first word line WL1 may be positioned on one side of the first active pattern AP1, and the second word line WL2 may be positioned on the other side of the second active pattern AP2. The first active patterns AP1 and the second active patterns AP2 may be positioned between the first word line WL1 and the second word line WL2 along the second direction Y.

The first word line WL1 and the second word line WL2 may be spaced apart from the bit lines BL and the contact patterns BC along the third direction Z. The first word line WL1 and the second word line WL2 may be positioned between the bit lines BL and the contact patterns BC.

The line parts SPa of the shield pattern SP positioned in the cell array region CAR may extend along a different direction from the first and second word lines WL1 and WL2 and overlap together along the third direction Z, which is a vertical direction to the substrate 200.

In an embodiment of the present invention, the end of the line parts SPa of the shield pattern SP may be aligned with the boundary of the side of the first and second word lines WL1 and WL2 positioned adjacent to the first periphery connection regions PCR1. For example, the end of the line parts SPa of the shield pattern SP may be aligned with the boundary substantially equivalent to the side of the second word line WL2 adjacent to the first periphery connection region PCR1. However, the position of the end of the line parts SPa of the shield pattern SP is not necessarily limited thereto and may be changed in various ways. For example, if the bit line insulation pattern 173 positioned in the first periphery connection region PCR1 extends further towards the cell array region CAR, the end of the line parts SPa of the shield pattern SP may be aligned to the boundary substantially equivalent to the side of the first and second active patterns AP1 and AP2 or the side of the back gate electrode BG, positioned adjacent to the first periphery connection region PCR1.

Each of the first word line WL1 and the second word line WL2 may have a width along the second direction Y. The width of the first and second word lines WL1 and WL2 may be different from the length of the first and second word lines WL1 and WL2. For example, the length of the first and second word lines WL1 and WL2 which is measured along the third direction Z, may be longer than the width of the first and second word lines WL1 and WL2. However, it is not necessarily limited thereto, and the width and the length of the first and second word lines WL1 and WL2 may be changed in various ways.

The first and second word lines WL1 and WL2 adjacent to each other may include opposing sides. The first and second word lines WL1 and WL2 may each include a first surface adjacent to the bit lines BL and a second surface adjacent to the contact patterns BC. For example, the first surfaces of the first and second word lines WL1 and WL2 may be disposed below the second surfaces of the first and second word lines WL1 and WL2.

The first surfaces of the first and second word lines WL1 and WL2 may have various shapes. For example, in some embodiments, the first and second word lines WL1 and WL2 each may have an L-shaped cross-section.

The height of the first and second word lines WL1 and WL2 measured along the third direction Z may be smaller than the height of the first and second active patterns AP1 and AP2 measured along the third direction Z. The height of the first and second word lines WL1 and WL2 along the third direction Z may be substantially equal to or smaller than the height of the back gate electrodes BG measured along the third direction Z.

The semiconductor device according to an embodiment of the present invention may further include a separation insulation patterns 300 positioned in the second periphery connection regions PCR2.

The separation insulation pattern 300 may penetrate the first and second word lines WL1 and WL2 in the second periphery connection regions PCR1 and PCR2 along the third direction Z, which is the vertical direction. For example, the first and second word lines WL1 and WL2 may be spaced apart by the separation insulation pattern 300 in between. For example, the first word line WL1 may extend along one side of the separation insulation pattern 300 along the second direction Y, the second word line WL2 may extend along the other side of the separation insulation pattern 300 along the second direction Y, and the ends of the first and second word lines WL1 and WL2 may be separated by the separation insulation pattern 300.

Accordingly, the first and second word lines WL1 and WL2 may be electrically separated and insulated from each other by the separation insulation patterns 300 in the second periphery connection regions PCR2.

In an embodiment of the present invention, the end of the separation insulation pattern 300 may protrude from the end of the plate part SPb of the shield pattern SP. For example, the end of the separation insulation pattern 300 may be positioned and separated further away from the cell array region CAR than the end of the shield pattern SP.

The first and second word lines WL1 and WL2 may include a conductive material. For example, the first and second word lines WL1 and WL2 may include any one of doped polysilicon, conductive metal nitride, conductive metal silicon nitride, metal carbon nitride, conductive metal silicide, conductive metal oxide, two-dimensional material, metal, or combination thereof.

The semiconductor device according to an embodiment of the present invention may further include a gate insulation pattern GOX, a gate capping pattern 143, first and second etching stopping layers 131 and 141, a first gate separation pattern 153, a second gate separation pattern 155, third and fourth etching stopping layers 211 and 213, and an interlayer insulating layer 231.

The gate insulation pattern GOX may be positioned between the first word line WL1 and the first active pattern AP1. The gate insulation pattern GOX may be positioned between the second word line WL2 and the second active patterns AP2. The gate insulation pattern GOX may extend parallel to the first and second word lines WL1 and WL2 along the first direction X.

The gate insulation pattern GOX may extend along the first side of the first active pattern AP1, have a substantially uniform thickness, and extend conformally along the second side of the second active pattern AP2.

The gate insulation pattern GOX may include vertical parts adjacent to the first and second active patterns AP1 and AP2, and horizontal parts protruding from the vertical part along the first direction X. A pair of the first and second word lines WL1 and WL2 may be positioned on the horizontal parts of each gate insulation pattern GOX. For example, the gate insulation pattern GOX between the first active pattern AP1 and the first word line WL1 may be separated from the gate insulation pattern GOX between the second active pattern AP2 and the second word line WL2.

The gate insulation pattern GOX may include an insulating material. For example, the gate insulation pattern GOX may include any one of a silicon oxide layer, a silicon oxynitride layer, a high dielectric layer having a higher dielectric constant than the silicon oxide layer, or a combination thereof.

The high dielectric layer may include a metal oxide or a metal oxynitride. For example, the high dielectric layer that may be used as the gate insulation pattern GOX may include any one of HfO₂, HfSiO, HfSiON, HfTaO, HfTIO, HfZrO, ZrO₂, Al₂O₃, or a combination thereof, but it is not necessarily limited thereto.

The gate capping pattern 143 may be positioned between the horizontal parts of the gate insulation pattern GOX and the contact patterns BC along the third direction Z.

The first and second etching stopping layers 131 and 141 may be placed between the second dopant regions SDR2 of the first and second active patterns AP1 and AP2 and the gate capping pattern 143. For example, the first etching stopping layer 131 may at least partially surround the gate capping pattern 143 and the second etching stopping layer 141 may be in contact with the gate capping pattern 143.

The gate capping pattern 143 and the first and second etching stopping layers 131 and 141 may include an insulating material. For example, the gate capping pattern 143 and the first and second etching stopping layers 131 and 141 may include any one of silicon oxide, silicon oxynitride, silicon nitride, or a combination thereof.

The first gate separation pattern 153 and the second gate separation pattern 155 may be positioned on bit lines BL. The first gate separation pattern 153 and the second gate separation pattern 155 may be placed between the bit lines BL and the gate insulation pattern GOX. The first gate separation pattern 153 and the second gate separation pattern 155 may be in direct contact with the bit lines BL. The first gate separation pattern 153 and the second gate separation pattern 155 may extend along the first direction X between the first word line WL1 and the second word line WL2.

Additionally, the first gate separation pattern 153 may be positioned between the second gate separation pattern 155 and the first and second word lines WL1 and WL2 along the second direction Y. The first gate separation pattern 153 may be in direct contact with the first and second word lines WL1 and WL2. The first gate separation pattern 153 may have a substantially uniform thickness and conformally extend along the sides of the gate insulation pattern GOX and the first and second word lines WL1 and WL2.

The first gate separation pattern 153 and the second gate separation pattern 155 may each include an insulating material. For example, the first gate separation pattern 153 and the second gate separation pattern 155 may include any one of silicon oxide, silicon oxynitride, silicon nitride, or a combination thereof.

The third and fourth etching stopping layers 211 and 213 and the interlayer insulating layer 231 may at least partially cover the second surfaces of the first and second active patterns AP1 and AP2 in the cell array region CAR.

The interlayer insulating layer 231 may extend from the cell array region CAR towards the periphery connection regions PCR and may at least partially cover an upper surface of an element isolation layer STI and a periphery gate electrode PG. The element isolation layer STI and the periphery gate electrode PG will be further described later.

The third and fourth etching stopping layers 211 and 213 and the interlayer insulating layer 231 may each include an insulating material. For example, the third and fourth etching stopping layers 211 and 213 may include any one of silicon oxide, silicon oxynitride, silicon nitride, or a combination thereof.

The semiconductor device according to an embodiment of the present invention may further include contact patterns BC, landing pads LP, a pad separation insulation pattern 245, fifth and sixth etching stopping layers 233 and 247, and an upper insulation layer 270.

The contact patterns BC may penetrate the third and fourth etching stopping layers 211 and 213 and the interlayer insulating layer 231. The contact patterns BC may be connected to the first and second active patterns AP1 and AP2, respectively. The contact patterns BC may be connected to the second surfaces of the first and second active patterns AP1 and AP2. For example, the contact patterns BC may be in contact with the second dopant regions SDR2 of the first and second active patterns AP1 and AP2, respectively. The contact patterns BC may have the lower width greater than the upper width in the cross-section. The contact patterns BC adjacent to each other may be separated from each other by the separation insulation patterns 245.

Each contact patterns BC may have various shapes when viewed in plan, such as circular, oval, rectangle, square, rhombus, and hexagon.

The contact patterns BC may include a conductive material.

For example, the contact patterns BC may include at least one of doped polysilicon, conductive metal nitride, conductive metal silicon nitride, metal carbon nitride, conductive metal silicide, conductive metal oxide, two-dimensional material, and metal.

The landing pads LP may be positioned on the contact patterns BC. The landing pads LP may have various shapes when viewed in plan, such as circular, oval, rectangle, square, rhombus, and hexagon.

The landing pads LP may include a conductive material. For example, the landing pads LP may include at least one of doped polysilicon, conductive metal nitride, conductive metal silicon nitride, metal carbon nitride, conductive metal silicide, conductive metal oxide, two-dimensional material, and metal.

The pad separation insulation patterns 245 may be placed between the landing pads LP. The landing pads LP may be arranged in a matrix pattern along the first direction X and the second direction Y when viewed in a plan. The upper surface of the landing pads LP may be substantially coplanar with the upper surface of the pad separation insulation pattern 245.

The fifth etching stopping layer 233 may be positioned between the interlayer insulating layer 231 and the sixth etching stopping layer 247 in the periphery connection regions PCR. The sixth etching stopping layer 247 may be placed on the pad separation insulation pattern 245.

The fifth and sixth etching stopping layers 233 and 247 may include an insulating material. For example, the fifth and sixth etching stopping layers 233 and 247 may include any one of silicon oxide, silicon oxynitride, silicon nitride, or a combination thereof.

The data storing patterns DSP may each be positioned on the landing pads LP in the cell array region CAR. The data storing patterns DSP may be electrically connected to the first and second active patterns AP1 and AP2, respectively.

The data storing patterns DSP, as shown in FIG. 1, may be arranged in a matrix format along the first direction X and the second direction Y. The data storing patterns DSP may completely or partially overlap the landing pads LP along the third direction Z. The data storing patterns DSP may be in contact with the entire or part of the upper surfaces of the landing pads LP.

For example, the data storing patterns DSP may be a capacitor. The data storing patterns DSP may include a capacitor dielectric layer 253 interposed between the storage electrodes 251 and the plate electrode 255. In this case, the storage electrode 251 may be in contact with the landing pads LP. The storage electrodes 251 may penetrate the sixth etching stopping layer 247.

The storage electrode 251 may have various shapes such as circular, oval, rectangle, square, rhombus, and hexagon in a plan view.

The data storing patterns DSP may completely or partially overlap the landing pads LP along the third direction Z. The data storing patterns DSP may be in contact with the entire or part of the upper surfaces of the landing pads LP.

In some embodiments of the present invention, the data storing patterns DSP may be a variable resistor pattern that may be switched between two resistance states by electrical pulses applied to memory elements. For example, the data storing patterns DSP may be a phase-change material of which a crystal state changes depending on the amount of a current, perovskite compounds, transition metal oxides, and magnetic materials, ferromagnetic materials or antiferromagnetic materials.

A memory cell contact plug connected to the plate electrode 255 may be placed on the data storing patterns DSP.

The upper insulation layer 270 may be positioned on the data storing patterns DSP. The upper insulation layer 270 may at least partially cover the plate electrode 255.

The upper insulation layer 270 may include an insulating material. For example, the upper insulation layer 270 may include at least one of silicon oxide, silicon oxynitride, silicon nitride, or a combination thereof.

The semiconductor device according to an embodiment may further include a periphery active pattern 110, an element isolation layer STI, a periphery gate insulating layer 215, a periphery gate electrode PG, first to third periphery connection wires 241a, 241b, and 241c, a peripheral circuit insulating layer 263, and periphery contact plugs PCPa and PCPb, which are placed in the periphery connection regions PCR of the substrate 200.

The periphery active pattern 110 may include the same material as the first and second active patterns AP1 and AP2 positioned in the cell array region CAR and may be positioned at a level substantially equivalent to the first and second active patterns AP1 and AP2.

The element isolation layer STI may be positioned in the periphery connection region PCR of the substrate 200. The element isolation layer STI may at least partially surround periphery active pattern 110. For example, the element isolation layer STI may at least partially surround the side of the periphery active pattern 110.

The periphery gate insulating layer 215 and the periphery gate electrode PG may be positioned sequentially on the periphery active pattern 110 along the third direction Z. The periphery gate electrode PG may be positioned on the periphery gate insulating layer 215. The periphery gate insulating layer 215 and the periphery gate electrode PG may be entirely covered by the interlayer insulating layer 231.

The periphery gate electrode PG may include a periphery conductive pattern 221, a periphery metal pattern 223, and a periphery mask pattern 225 that are sequentially stacked along the third direction Z. In FIG. 6, the periphery gate electrode PG is illustrated as including two conductive material layers, but the present disclosure is not necessarily limited thereto, and the number of the conductive material layers included in the periphery gate electrode PG may be three or more.

The periphery gate electrode PG may be a gate electrode of a peripheral circuit transistor. For example, the peripheral circuit transistor may configure row and column decoders, sense amplifiers, or control logics. However, the type and role of the peripheral circuit transistor are not necessarily limited thereto and may vary depending on the design of the semiconductor device.

The element isolation layer STI and the periphery gate insulating layer 215 may include an insulating material. For example, the element isolation layer STI and the periphery gate insulating layer 215 may include any one of silicon oxide, silicon oxynitride, silicon nitride or a combination thereof.

The plurality of bit line contact plugs BCNT may be connected to the ends of bit lines BL in the first periphery connection regions PCR1. In a plan view, the width of each of the plurality of bit line contact plugs BCNT may be larger than the width of each bit lines BL. In FIG. 1, FIG. 4, and FIG. 5, the bit line contact plugs BCNT are illustrated as having a circular shape in a plan view, but this is not necessarily limited to thereto and may be changed in various ways. For example, the bit line contact plugs BCNT may have various shapes in a plan view, such as oval, rectangle, square, rhombus, or hexagon.

In an embodiment of the present invention, parts of the bit line contact plugs BCNT may be respectively connected to the ends of some bit lines BL positioned in the first periphery connection region PCR1 on one side along the second direction Y, and the remaining parts may be respectively connected to the ends of the remaining bit lines BL in the first periphery connection region PCR1 on the other side along the second direction Y. For example, the plurality of bit line contact plugs BCNT may be alternatively connected to the ends of the bit lines BL positioned on one side along the second direction Y and the ends of the bit lines BL positioned on the other side along the second direction Y. For example, some of the plurality of bit line contact plugs BCNT may be positioned in the first periphery connection region PCR1 located on one side along the second direction Y, and the remaining portions may be positioned in the first periphery connection region PCR1 positioned on the other side along the second direction Y. The plurality of bit line contact plugs BCNT may be connected to the ends of the different bit lines BL. However, the arrangement form of the bit line contact plug BCNT is necessarily not limited thereto and may be changed in various ways.

The bit line contact plugs BCNT may be connected to the ends of the bit lines BL through the fifth etching stopping layer 233, the interlayer insulating layer 231, and the element isolation layer STI. For example, the bottom surface BCNT_B of the bit line contact plugs BCNT may be in direct contact with the upper surface BL_T of the bit lines BL. Here, the upper surface BL_T of the bit lines BL may refer to the upper surface of the metal layer 163 of the bit lines BL. The bit lines BL and the first periphery connection wire 241a may be electrically connected by the bit line contact plug BCNT.

The bit line contact plug BCNT may have a shape that the width along the first direction X narrows as it approaches the substrate 200 depending on the aspect ratio on the cross-section. For example, the width of the upper surface BCNT_T of the bit line contact plug BCNT may be larger than the width of the bottom surface BCNT_B of the bit line contact plug BCNT.

The width of the bottom surface BCNT_B of the bit line contact plug BCNT may be larger than the width of the upper surface BL_T of the bit lines BL. As the width of the bottom surface BCNT_B of the bit line contact plug BCNT is greater than the width of the upper surface BL_T of the bit lines BL, the bottom surface BCNT_B of the bit line contact plug BCNT may at least partially cover the upper surface BL_T of the bit lines BL.

In addition, as the width of the bottom surface BCNT_B of the bit line contact plug BCNT may be larger than the width of the upper surface BL_T of the bit lines BL, the bit line contact plugs BCNT may overlap with the bit lines BL and a portion of the bit line insulation pattern 173 positioned between the adjacent bit lines BL.

In the process of forming the bit line contact plug BCNT, the bit line contact plug BCNT may recess a portion of the bit line insulation pattern 173. For example, the bit line contact plug BCNT may have a shape that penetrates a part of the bit line insulation pattern 173 positioned adjacent to the bit lines BL on the cross-section. Accordingly, the bottom surface BCNT_B of the bit line contact plug BCNT may be positioned at the lower level than the upper surface 173_T of the bit line insulation pattern 173. However, the arrangement of the bit line contact plug BCNT and the bit lines BL, the arrangement of the bit line contact plug BCNT and the bit line insulation pattern 173, and the shape on the cross-section of the bit line contact plug BCNT are not necessarily limited thereto and may be variously changed.

The plurality of bit line contact plugs BCNT may be connected to the end of the bit lines BL in the first periphery connection regions PCR1. In a plan view, the width of each of the plurality of bit line contact plugs BCNT may be larger than the width of each bit lines BL. In FIG. 1, FIG. 4, and FIG. 5, the bit line contact plugs BCNT is illustrated as having a circular in a plan view, but it is not necessarily limited thereto and may be changed in various ways. For example, the bit line contact plugs BCNT may have various shapes on a plane, such as oval, rectangle, square, rhombus, and hexagon.

In an embodiment of the present invention, parts of the bit line contact plugs BCNT may be respectively connected to the ends of some of the bit lines BL positioned in the first periphery connection region PCR1 disposed on one side along the second direction Y. The remaining parts of the bit line contact plugs BCNT may be respectively connected to the ends of the remaining bit lines BL in the first periphery connection region PCR1 disposed on the other along the second direction Y. For example, the plurality of bit line contact plugs BCNT may be alternatively connected to the ends of the bit lines BL positioned on one side in the second direction Y and the ends of the bit lines BL positioned on the other side along the second direction Y. For example, some of the plurality of bit line contact plugs BCNT may be positioned in the first periphery connection region PCR1 located on one side along the second direction Y, and the remaining portions may be positioned in the first periphery connection region PCR1 positioned on the other side along the second direction Y, and may be connected to the ends of the different bit lines BL. However, the arrangement form of the bit line contact plug BCNT is not necessarily limited to this and may be changed in various ways.

The plurality of shield pattern contact plugs SCNT may be connected to the plate part SPb of the shield pattern SP in the second periphery connection regions PCR2. In FIG. 1, the shield pattern contact plugs SCNT is illustrated as having a circular in a plan view, but it is not necessarily limited thereto and may be changed in various ways. For example, the shield pattern contact plugs SCNT may have various shapes in a plan view, such as oval, rectangle, square, rhombus, and hexagon.

In an embodiment of the present invention, the plurality of shield pattern contact plugs SCNT may be positioned on the end of the plate part SPb of the shield pattern SP which is positioned in the second periphery connection regions PCR2. For example, the shield pattern contact plugs SCNT may be positioned at each corner of the plate part SPb of the shield pattern SP. However, the arrangement and number of the plurality of shield pattern contact plug SCNTs are not necessarily limited thereto and may be changed in various ways.

The shield pattern contact plug SCNT may have a shape that the width in the first direction X becomes narrower as it approaches the substrate 200. The shield pattern contact plug SCNT may be connected to the plate part SPb of the shield pattern SP through the fifth etching stopping layer 233, the interlayer insulating layer 231, and the element isolation layer STI. The shield pattern SP and the second periphery connection wire 241b may be electrically connected by the shield pattern contact plug SCNT.

The semiconductor device according to an embodiment of the present invention may further include a first periphery contact plug PCPa connected to the peripheral circuit structure PS in the first periphery connection regions PCR1 and a second periphery contact plug PCPb connected to the peripheral circuit transistor.

The first periphery contact plug PCPa may be connected to the metal pattern PCL positioned in the peripheral circuit structure PS while sequentially penetrating the fifth etching stopping layer 233, the interlayer insulating layer 231, the element isolation layer STI, the spacer insulating layer 171, the capping insulating layer 175, the planarization insulating layer 180 of the cell array structure CS in the first periphery connection regions PCR1, and the peripheral circuit insulating layers ILD of the peripheral circuit structure PS.

As the first periphery contact plug PCPa is connected to the first periphery connection wire 241a of the cell array structure CS and the metal pattern PCL of the peripheral circuit structure PS, the cell array structure CS and the peripheral circuit structure PS may be electrically connected to the first periphery contact plug PCPa. For example, the bit lines BL and the peripheral circuit structure PS may be connected by the bit line contact plug BCNT and the first periphery contact plug PCPa which is connected to the first periphery connection wire 241a. However, the arrangement of the first periphery contact plug PCPa and the connection relationship with other components are not necessarily limited thereto and may be changed in various ways.

The second periphery contact plug PCPc may be connected to a source/drain region of the periphery transistor through the fifth etching stopping layer 233, the interlayer insulating layer 231, and the periphery gate insulating layer 215 in the first periphery connection regions PCR1. For example, the second periphery contact plug PCPc may be connected to the source/drain region of the periphery transistor which is positioned at least on one side of the periphery gate electrode PG.

The first periphery contact plug PCPa and the second periphery contact plug PCPb have a shape that the width becomes narrower along first direction X as it approaches the substrate 200 depending on the aspect ratio on the cross-section. However, the cross-section shape of the first periphery contact plug PCPa and the second periphery contact plug PCPb is not necessarily limited thereto and may be changed in various ways.

The bit line contact plug BCNT, the shield pattern contact plug SCNT, the first periphery contact plug PCPa, and the second periphery contact plug PCPb may include a conductive material. For example, the bit line contact plug BCNT, the shield pattern contact plug SCNT, the first periphery contact plug PCPa, and the second periphery contact plug PCPb may include at least one of metals or combinations thereof such as aluminum (Al), tungsten (W), titanium (Ti), tantalum (Ta), copper (Cu), etc. However, the conductive material is not necessarily limited thereto and may be changed in various ways.

FIG. 6 shows that the first periphery contact plug PCPa and the second periphery contact plug PCPb are positioned in the first periphery connection regions PCR1, but it is not necessarily limited thereto, and the first periphery contact plug PCPa and the second periphery contact plug PCPb may be positioned in the second periphery connection region PCR2.

The pad separation insulation pattern 245 may insulate the first, second, and third periphery connection wires 241a, 241b, and 241c in the first and second periphery connection regions PCR1 and PCR2. The sixth etching stopping layer 247 may at least partially cover the upper surface of the first, second, and third periphery connection wires 241a, 241b, and 241c in the first and second periphery connection regions PCR1 and PCR2.

In the first and second periphery connection regions PCR1 and PCR2, the peripheral circuit insulating layer 263 and the upper insulation layer 270 may be positioned sequentially on the sixth etching stopping layer 247. For example, the peripheral circuit insulating layer 263 may be interposed between the upper insulation layer 270 and the sixth etching stopping layer 247.

In the semiconductor device according to an embodiment of the present invention, as the length of the line part SPa of the shield pattern SP positioned between the adjacent bit lines BL is shorter than the length of the bit lines BL, the bit line insulation pattern 173 instead of the line part SPa of the shield pattern SP may be positioned between the adjacent bit lines BL in the first periphery connection regions PCR1 in which the bit line contact plug BCNT and the bit lines BL are connected.

In this way, as the bit line insulation pattern 173 including the insulating material is positioned between the ends of the adjacent bit lines BL instead of the shield pattern SP including the conductive material. Thus, even if the bit line contact plug BCNT has a larger width than the bit lines BL, the bit line contact plug BCNT is prevented from being in contact with the line parts SPa of the shield pattern SP and simultaneously the contact margin between the bit line contact plug BCNT and the bit lines BL may be secured.

In addition, instead of securing an additional region to secure the contact margin of the bit line contact plug BCNT and the bit lines BL, by forming the bit line insulation pattern 173 between the ends of the adjacent bit lines BL, the integration of the semiconductor device may be improved by securing the contact margin of the bit line contact plug BCNT and the bit lines BL.

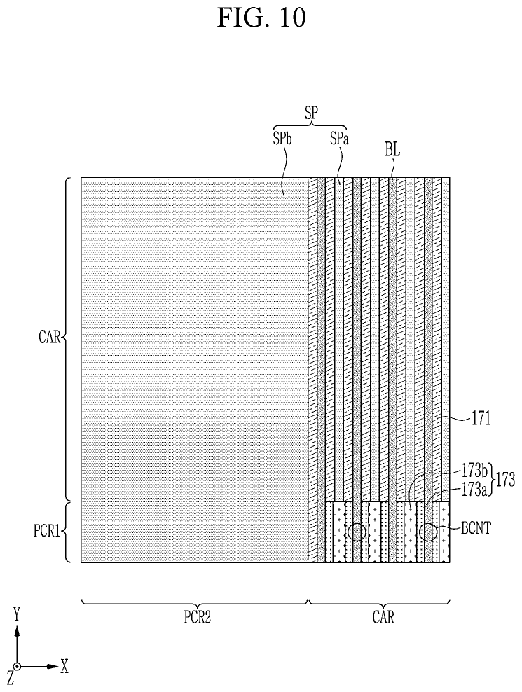

Hereinafter, the semiconductor devices according to various embodiments of the present invention are described with reference to FIG. 10 to FIG. 22. To the extent that an element has not been described in detail, it may be assumed that the element is at least similar to corresponding elements that have been described in previous figures.

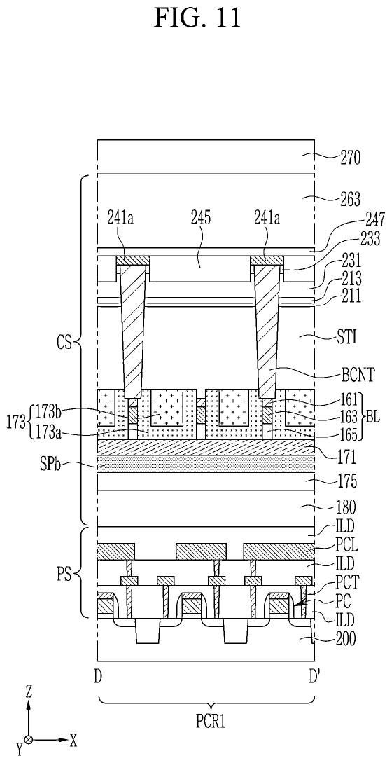

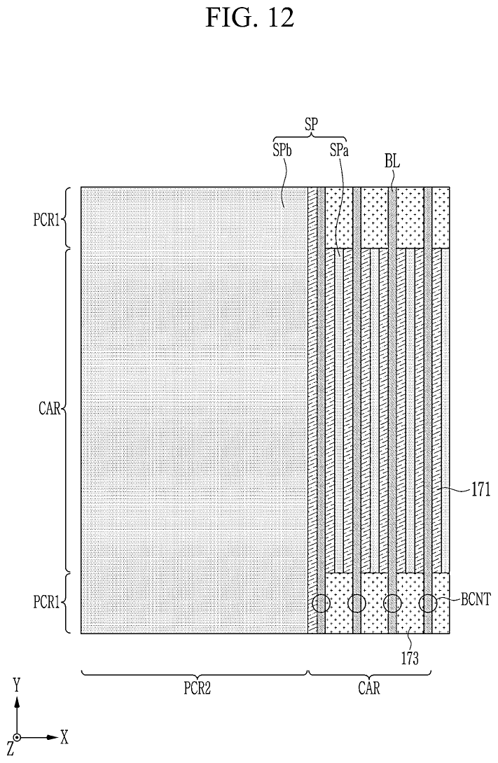

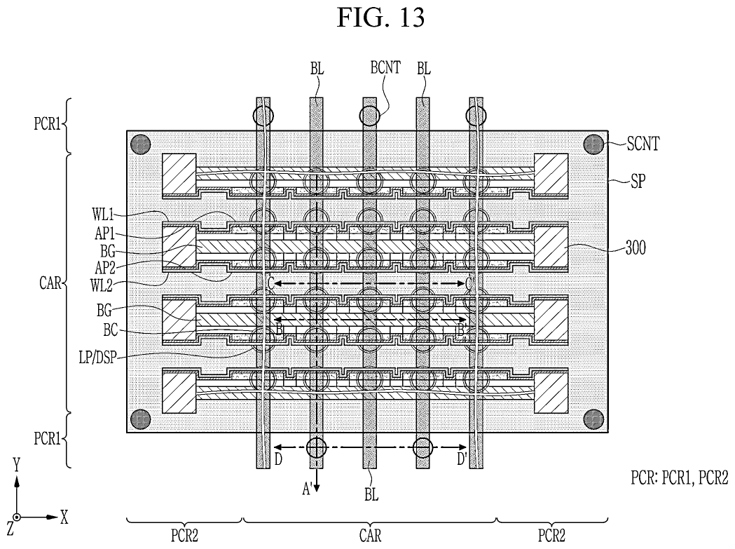

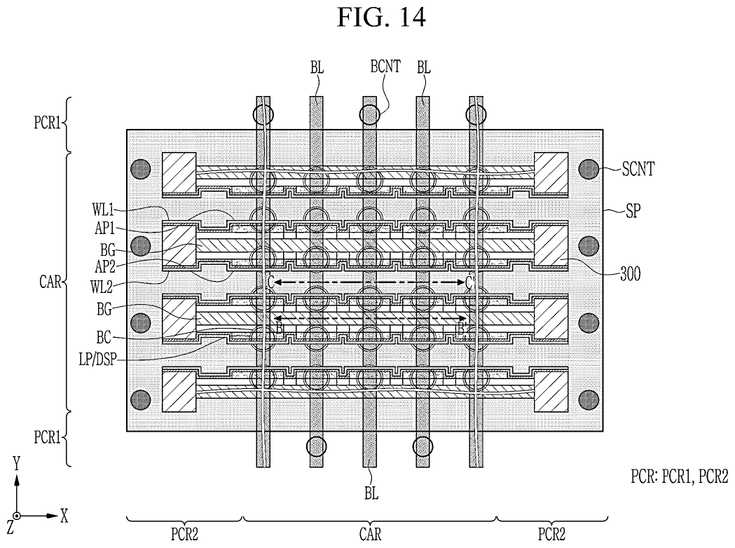

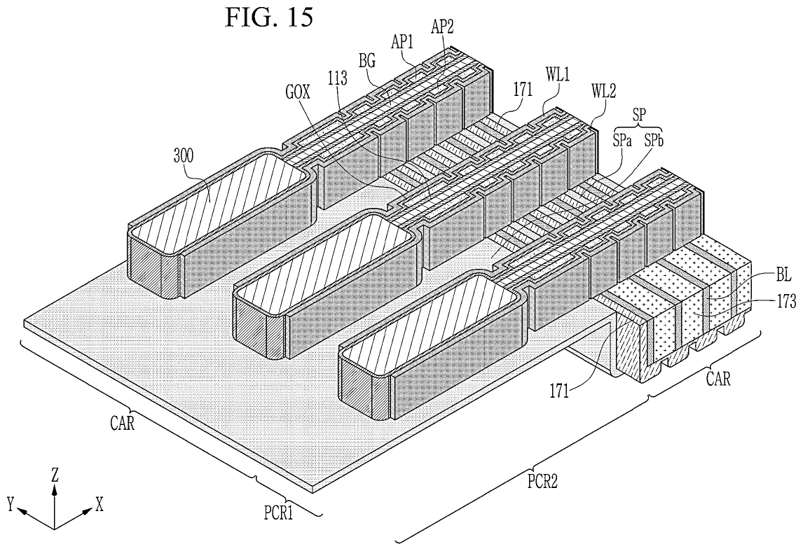

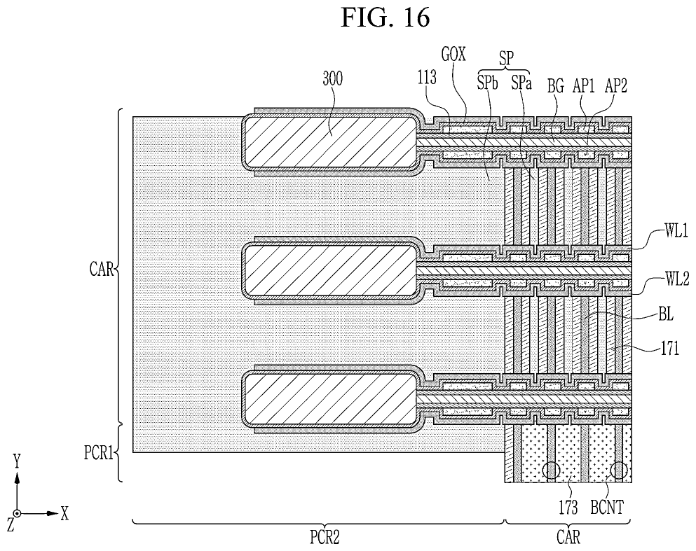

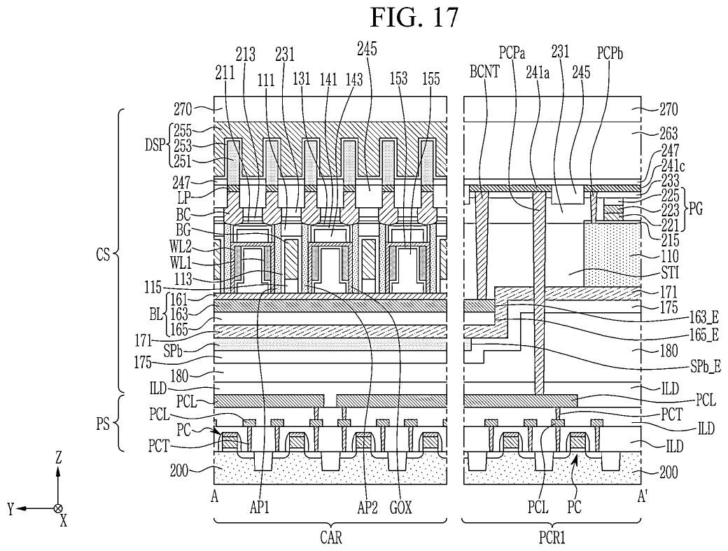

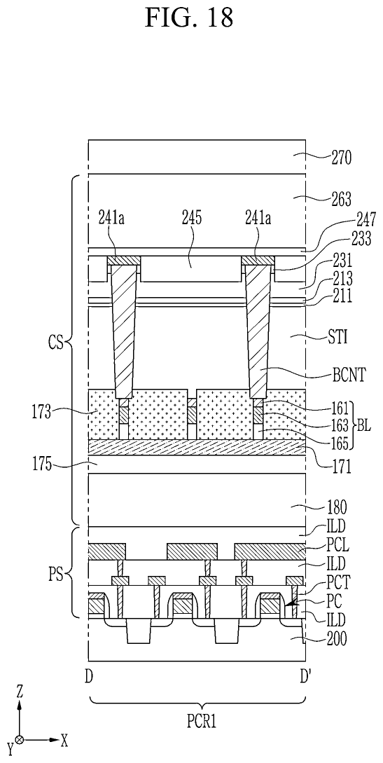

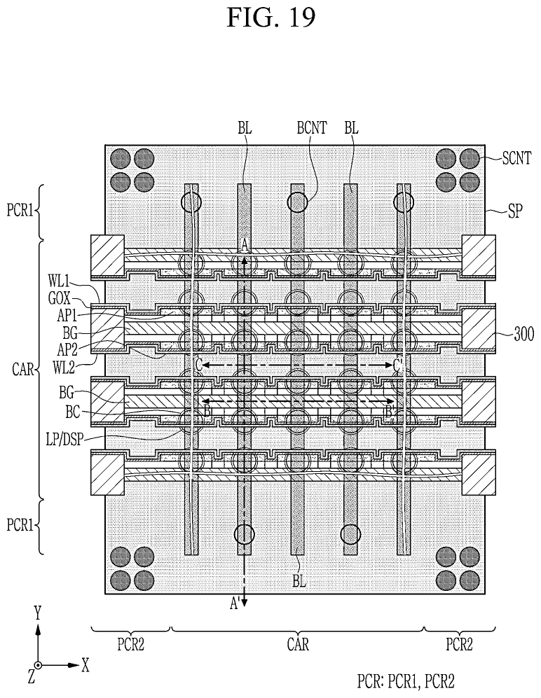

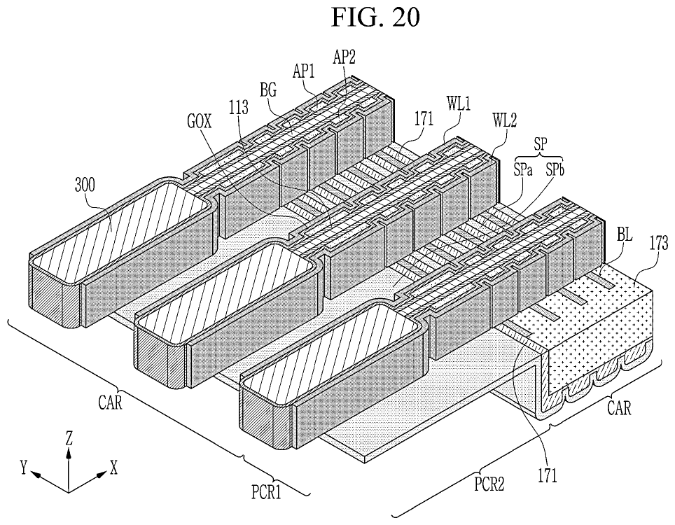

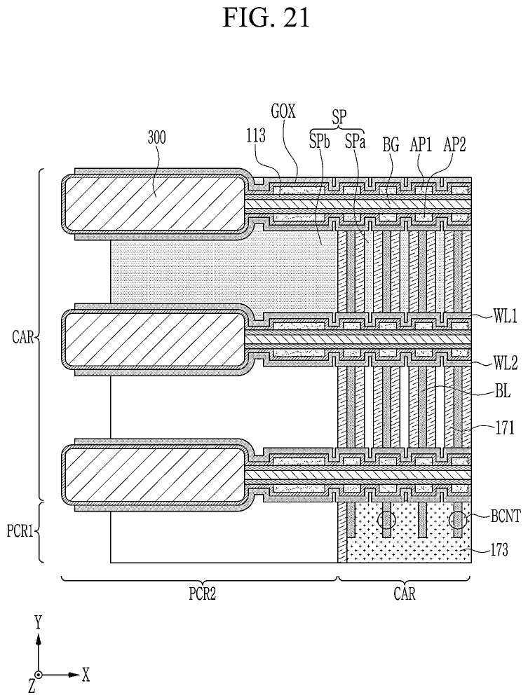

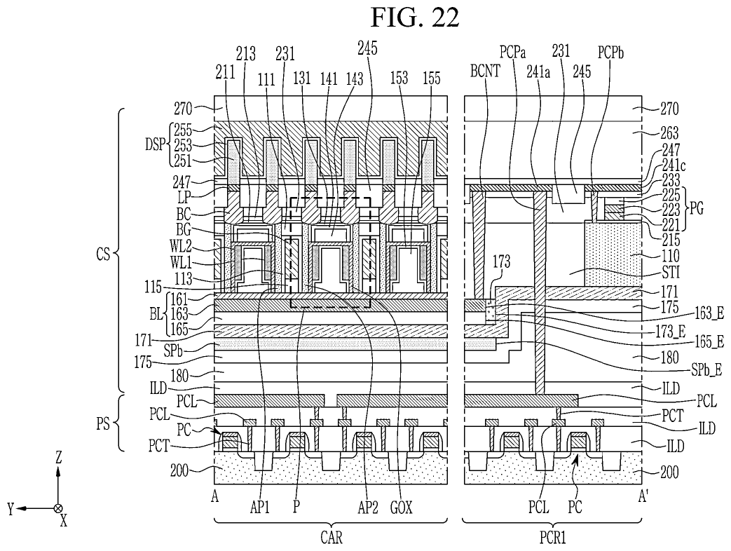

FIG. 10 and FIG. 12 are partial layout views illustrating a bit line, shield pattern, a spacer insulating layer, a bit line insulation pattern, and a bit line contact plug of a semiconductor device according to some embodiments of the present invention. FIG. 11 is a cross-sectional view cut along a line D-D′ of FIG. 1 according to some embodiments of the present invention. FIG. 13, FIG. 14, and FIG. 19 are layout views of a semiconductor device according to some embodiments of the present invention. FIG. 15 and FIG. 20 are partial perspective views of a semiconductor device according to some embodiments of the present invention. FIG. 16 and FIG. 21 are partial layout views of a semiconductor device according to some embodiments of the present invention. FIG. 17 is a cross-sectional view cut along a line A-A′ in FIG. 13. according to some embodiments of the present invention. FIG. 18 is a cross-sectional view cut along a line D-D′ in FIG. 3. according to some embodiments of the present invention. FIG. 22 is a cross-sectional view cut along a line A-A′ in FIG. 19. according to some embodiments of the present invention.

According to the embodiment shown in FIG. 10 and FIG. 11, unlike the embodiment shown in FIG. 5 and FIG. 9, the bit line insulation pattern 173 is composed of a plurality of layers.

For example, referring to, FIG. 10 and FIG. 11, the bit line insulation pattern 173 positioned between the bit lines BL adjacent to each other which are positioned in the first periphery connection region PCR1 may include a first bit line insulation pattern 173a and a second bit line insulation pattern 173b.

The first bit line insulation pattern 173a and the second bit line insulation pattern 173b may be sequentially positioned between the adjacent bit lines BL along the first direction X.

The first bit line insulation pattern 173a may conformally extend with a substantially uniform thickness between the adjacent bit lines BL along the sides of the bit lines BL and the upper surface of the spacer insulating layer 171. Accordingly, the first bit line insulation pattern 173a may define a gap region between the adjacent bit lines BL.

The second bit line insulation pattern 173b may be positioned on the first bit line insulation pattern 173a. For example, the second bit line insulation pattern 173b may be positioned within the gap region which is defined by the first bit line insulation pattern 173a between the adjacent bit lines BL.

Accordingly, the bottom surface and both sides of the second bit line insulation pattern 173b may be at least partially surrounded by the first bit line insulation pattern 173a.

The width of the second bit line insulation pattern 173b may be larger than the width of the first bit line insulation pattern 173a. Here, the width of the first bit line insulation pattern 173a and the width of the second bit line insulation pattern 173b may mean the length along the first direction X or the third direction Z. However, the relationship between the placement and width of the first bit line insulation pattern 173a and the second bit line insulation pattern 173b is not necessarily limited to this and may be changed in various ways.

The upper surface of the first bit line insulation pattern 173a and the upper surface of the second bit line insulation pattern 173b may be positioned at a higher level than the upper surface BL_T of the bit lines BL. However, it is not necessarily limited to this, and at least one of the upper surface of the first bit line insulation pattern 173a and the upper surface of the second bit line insulation pattern 173b may be positioned at a level substantially equivalent to the upper surface BL_T of the bit lines BL.

The bit line contact plugs BCNT connected to the bit lines BL may overlap the first bit line insulation pattern 173a and might not overlap the second bit line insulation pattern 173b. The bit line contact plug BCNT may be in direct contact with the first bit line insulation pattern 173a, and may recess a part of the first bit line insulation pattern 173a. For example, a part of the bit line contact plug BCNT may have a shape that penetrates the part of the first bit line insulation pattern 173a on the cross-section. However, the arrangement relationship between the bit line contact plug BCNT and the bit line insulation pattern 173 is not necessarily limited to this and may be changed in various ways. For example, the bit line contact plug BCNT may overlap the first bit line insulation pattern 173a and the second bit line insulation pattern 173b, and the bit line contact plug BCNT may recess a portion of the second bit line insulation pattern 173b.

According to the present embodiment, the first bit line insulation pattern 173a and the second bit line insulation pattern 173b may include different materials. For example, the first bit line insulation pattern 173a may include a silicon nitride-based material, and the second bit line insulation pattern 173b may include a silicon oxide-based material. However, this is an example, and the materials included in the first bit line insulation pattern 173a and the second bit line insulation pattern 173b are not necessarily limited thereto and may be changed in various ways.

In the case of the semiconductor device according to the embodiment, as the bit line insulation pattern 173 is positioned between the ends of the adjacent bit lines BL which are positioned in the first periphery connection region PCR1, the substantially equivalent effect to the semiconductor device according to the previous embodiment may be obtained.

In addition, as the bit line insulation pattern 173 is composed of the first bit line insulation pattern 173a and the second bit line insulation pattern 173b including different materials, in the process of forming the semiconductor device, the bit line insulation pattern 173 may be stably formed between the adjacent bit lines BL and may prevent a damage to the bit lines BL.

In addition, as the bit line insulation pattern 173 is composed of the first bit line insulation pattern 173a and the second bit line insulation pattern 173b including different materials, the coupling capacitance due to a mutual interference between the adjacent bit lines BL may be reduced. For example, as the first bit line insulation pattern 173a may include a material with a relatively lower dielectric constant compared to the second bit line insulation pattern 173b and may surround the second bit line insulation pattern 173b, the coupling due to the mutual interference between adjacent bit lines BL may be reduced.

According to an embodiment shown in FIG. 12, unlike the embodiment shown in FIG. 5, the bit line contact plug BCNT located in the first periphery connection regions PCR1 is modified.

For example, referring to FIG. 12, the plurality of bit line contact plugs BCNT may be connected to the bit lines BL by positioning only one of the first periphery connection region PCR1, which is positioned on one side or the other side of the cell array region CAR along the second direction Y.

For example, the plurality of bit line contact plugs BCNT may only be positioned in the first periphery connection region PCR1, which is positioned on one side of the second direction Y of the cell array region CAR. For example, the plurality of bit line contact plugs BCNT may be arranged side by side along the first direction X in the first periphery connection region PCR1 positioned at one side in the second direction Y and may be respectively connected to the end of the bit lines BL positioned in the first periphery connection region PCR1. However, the arrangement form of the plurality of bit line contact plug BCNT on a plane is not necessarily limited thereto and may be changed in various ways. For example, the bit line contact plugs BCNT may be arranged in a zigzag shape in the second direction Y.

According to the present embodiment, in the case of the semiconductor device, since the contact margin of the bit line contact plug BCNT and the bit lines BL may be sufficiently secured by the bit line insulation pattern 173 between the adjacent bit lines BL, the plurality of bit line contact plug BCNT may be arranged side by side to each other at the end of one side of the bit lines BL.

Accordingly, the design of the semiconductor device may be diversified by placing other components in the remaining first periphery connection region PCR1 where the bit line contact plug BCNT is not positioned. The integration of the semiconductor device may be improved by reducing the length of the bit lines BL and prevent the end of bit lines BL from being positioned in the remaining first periphery connection region PCR1 where the bit line contact plug BCNT is not positioned.

As illustrated in FIG. 13 to FIG. 18, the semiconductor device according to an embodiment of the present invention, the placement of the plate part (SPb) of the shield pattern SP may be modified.

For example, referring to, FIG. 13 to FIG. 16, the length of the plate part SPb of the shield pattern SP along the first direction X may be longer than the length of the first and second word lines WL1 and WL2 along the first direction X, and the length of the plate part SPb of the shield pattern SP along the second direction Y may be shorter than the length of the bit lines BL along the second direction Y.

For example, the end of the plate part SPb of the shield pattern SP may be positioned further away from the cell array region CAR to one side and the opposite side along the first direction X than the ends of the first and second word lines WL1 and WL2. Thus, the first and second word lines WL1 and WL2 positioned in the second periphery connection regions PCR2 may completely overlap the plate part SPb of the shield pattern SP along the third direction Z that is a direction vertical to the substrate 200.

In the present embodiment, the arrangement form of the shield pattern contact plug SCNT may be substantially equivalent to the arrangement form of the shield pattern contact plug SCNT according to an embodiment. For example, in the present embodiment, the shield pattern contact plugs SCNT may be positioned at the end, which is the corner of the plate part SPb of the shield pattern SP in the second periphery connection region PCR2. However, in the present embodiment, as the plate part SPb of the shield pattern SP further extends to one side and the other side in the first direction X, the area of the second periphery connection region PCR2 may be relatively wider than the area of the second periphery connection region PCR2.

Accordingly, in the second periphery connection region PCR2 of the present embodiment, the separation distance between the shield pattern contact plug SCNT and the first and second word lines WL1 and WL2 positioned at the end of the plate part SPb of the shield pattern SP, the corner, may be greater than the separation distance between the shield pattern contact plug SCNT and the first and second word lines WL1 and WL2.

Also, in the present embodiment, as the area of the plate part SPb of the shield pattern SP positioned in the second periphery connection region PCR2 is relatively wider than the area of the plate part SPb of the shield pattern SP positioned in the second periphery connection region PCR2, the arrangement shape and number of the shield pattern contact plugs SCNT positioned in the second periphery connection regions PCR2 may vary.

For example, as illustrated in FIG. 14, the shield pattern contact plugs SCNT positioned in the second periphery connection regions PCR2 may be arranged in parallel along the second direction Y, and the number of the shield pattern contact plugs SCNT positioned in the second periphery connection region PCR2 may be greater than the number of the shield pattern contact plugs SCNT shown in FIG. 13. For example, the shield pattern contact plugs SCNT may overlap with the separation insulation pattern 300 along the first direction X and may be arranged in a row along the second direction Y. However, the arrangement form and number of the shield pattern contact plugs SCNT shown in FIG. 14 are not necessarily limited thereto, and may be changed in various ways.

As shown in FIG. 14, when the number of shield pattern contact plugs SCNT increases, the electrical resistance of the shield pattern SP may be reduced. Accordingly, the electric characteristic of the semiconductor device may be improved.

Further referring to FIG. 17 and FIG. 18 along with FIG. 13 to FIG. 16, in the present embodiment, the length of the plate part SPb of the shield pattern SP along the second direction Y may be different from the length of the line parts SPa of the shield pattern SP along the second direction Y and the length of the bit lines BL along the second direction Y. For example, in the present embodiment, the length of the plate part SPb of the shield pattern SP along the second direction Y may be longer than the length of the line parts SPa of the shield pattern SP along the second direction Y and shorter than the length of the bit lines BL along the second direction Y.

The end of the plate part SPb of the shield pattern SP may be positioned in a protruding manner rather than being aligned to the sides of the first and second word lines WL1 and WL2 which are positioned adjacent to the first periphery connection regions PCR1 along the second direction Y. For example, the end of the plate part SPb of the shield pattern SP may be positioned between the sides of the first and second word lines WL1 and WL2 which are positioned adjacent to the first periphery connection regions PCR1 that is positioned at one side and the other side along the second direction Y and the end of the bit lines BL which is positioned in the first periphery connection regions PCR1.

For example, the end of the line parts SPa of the shield pattern SP may be positioned in the cell array region CAR, the end of the plate part SPb of the shield pattern SP and the end of the end of the bit lines BL may be positioned in the first periphery connection regions PCR1, and the end of the bit lines BL may be positioned separated further from the cell array region CAR than the end of the plate part SPb of the shield pattern SP. For example, as illustrated in FIG. 17, the end SPb_E of the plate part SPb of the shield pattern SP, the end 163_E of the metal layer 163 of the bit lines BL, and the end 165_E of the bit line hard mask layer 165 may be positioned in the first periphery connection region PCR1 and may be aligned on the different boundaries from each other. However, the length relationship of the line parts SPa and plate part SPb of the shield pattern SP along the second direction Y is not necessarily limited thereto and may be changed in various ways. For example, in some embodiments, the lengths of the line parts SPa and the plate parts SPb of the shield pattern SP along the second direction Y may be substantially equivalent.

Accordingly, as shown in FIG. 17 and FIG. 18, the bit line contact plugs BCNT connected to the end of the bit lines BL and the plate part SPb of the shield pattern SP might not overlap along the third direction Z that is a direction vertical to the substrate 200. For example, as the end of the bit lines BL is extended and positioned further along the second direction Y compared to the end of the plate part SPb of the shield pattern SP, the bit line contact plug BCNT connected to the end of the bit lines BL might not overlap with the end of the plate part SPb of the shield pattern SP positioned below the bit lines BL.

In FIG. 15 to FIG. 18, the first periphery connection region PCR1 positioned at one side of the cell array region CAR in the second direction Y and the second periphery connection region PCR2 positioned at one side in the first direction X are illustrated. The first periphery connection region PCR1 positioned at the other side of the cell array region CAR in the second direction Y and the second periphery connection region PCR2 positioned at the other side in the first direction X are not illustrated. However, the aforementioned applies to the configurations located in the first periphery connection region PCR1 on one side of the cell array region CAR along the Y-axis and the second periphery connection region PCR2 on one side along the X-axis, and the arrangement relationship between these configurations may be substantially equivalently applied to the configurations in the first periphery connection region PCR1 on the opposite side of the cell array region CAR along the Y-axis and the second periphery connection region PCR2 on the opposite side along the X-axis, and the arrangement relationship between these configurations.

In the case of the semiconductor device of the present embodiment, as the bit line insulation pattern 173 is positioned between the ends of the adjacent bit lines BL positioned in the first periphery connection region PCR1, the substantially equivalent effect to that of the semiconductor device according to the previous embodiment may be achieved.

In addition, as the length of the plate part SPb of the shield pattern SP along the second direction Y is shorter than the length of the bit lines BL along the second direction Y, the bit line contact plug BCNT connected to the end of the bit lines BL T and the plate part SPb of the shield pattern SP might not overlap in the vertical direction.

Accordingly, in the process of forming the bit line contact plug BCNT, as the bit lines BL is penetrated by the bit line contact plug BCNT, the electric characteristic of the semiconductor device may be improved by preventing the bit line contact plug BCNT and the plate part SPb of the shield pattern SP positioned below the bit lines BL from being connected. For example, in the process of forming the bit line contact plug BCNT, though the bit line contact plug BCNT penetrates the bit lines BL, as the end of the bit lines BL and the end of the plate part SPb of the shield pattern SP do not overlap, the bit line contact plug BCNT may be prevented from being connected to the shield pattern SP.

According to an embodiment shown in FIG. 19 to FIG. 22, the placement of the plate part SPb of the shield pattern SP is modified.

For example, referring to FIG. 19 to FIG. 21, the length of the plate part SPb of the shield pattern SP along the second direction Y may be longer than the length of the bit lines BL along the second direction Y.

In the present embodiment, the arrangement form of the shield pattern contact plug SCNT may be substantially equivalent to the arrangement form of the shield pattern contact plug SCNT according to an embodiment. For example, in the present embodiment, the shield pattern contact plugs SCNT may be positioned at the end, the corner, of the plate part SPb of the shield pattern SP in the second periphery connection region PCR2. However, in the present embodiment, as the plate part SPb of the shield pattern SP extends further towards one side and the opposite side along the second direction Y, the area of the second periphery connection region PCR2 may be wider relative to the area of the second periphery connection region PCR2.

Accordingly, in the present embodiment, the number of the shield pattern contact plugs SCNT positioned at the end, the corner portion, of the plate part SPb of the shield pattern SP in the second peripheral connection region PCR2 may increase.

As illustrated in FIG. 19, in the present embodiment, the shield pattern contact plugs SCNT are arranged in a matrix format at the corner of the plate part SPb of the shield pattern SP which is located in the second periphery connection regions PCR2 viewed in a plan. The number of the shield pattern contact plugs SCNT positioned at the corner of the plate part SPb of the shield pattern SP may be greater than the number of the shield pattern contact plugs SCNT according to the embodiment illustrated in FIG. 13. However, the arrangement form and number of the shield pattern contact plugs SCNT shown in FIG. 19 are not necessarily limited thereto, and may be changed in various ways.

For example, the shield pattern contact plugs SCNT may be positioned only on some of the plurality of corners of the plate part SPb of the shield pattern SP which is positioned in the second periphery connection region PCR2. For example, the plurality of shield pattern contact plugs SCNT may be concentrated and positioned only on some of the plurality of corners of the plate part SPb of the shield pattern SP. For example, the shield pattern contact plug SCNT may be positioned only in some of the plurality of corners of the plate part SPb of the shield pattern SP, and the shield pattern contact plug SCNT might not be positioned in the remaining part of the plate part SPb of the shield pattern SP.

In some embodiments, the shield pattern contact plugs SCNT may be positioned on the plate part SPb of the shield pattern SP positioned on the first periphery connection regions PCR1. For example, the shield pattern contact plugs SCNT may be arranged side by side along the first direction X in the first periphery connection regions PCR1.

As illustrated in FIG. 19, as the area of the plate part SPb of the shield pattern SP increases, the arrangement and number of the shield pattern contact plugs SCNT may be changed in various ways. Accordingly, the design of the semiconductor device may be diversified, and the electrical resistance of the shield pattern SP may be adjusted by changing the number of shield pattern contact plugs SCNT.

Referring further FIG. 20. to FIG. 22 together FIG. 19, in the present embodiment, the length of the plate part SPb of the shield pattern SP along the second direction Y may be longer than the length of the line parts SPa of the shield pattern SP along the second direction Y and the length of the bit lines BL along the second direction Y.

For example, the end of the plate part SPb of the shield pattern SP and the end of the bit lines BL may be positioned in the first periphery connection regions PCR1, and the end of the plate part SPb of the shield pattern SP may be positioned further away from the cell array region CAR than the end of the bit lines BL. For example, as illustrated in FIG. 22, the end SPb_E of the plate part SPb of the shield pattern SP, the end 163_E of the metal layer 163 of the bit lines BL, and the end 165_E of the bit line hard mask layer 165 may be aligned at the different boundaries in the first periphery connection region PCR1. For example, the end SPb_E of the plate part SPb of the shield pattern SP may be positioned further away from the cell array region CAR in the second direction Y than the end 163_E of the metal layer 163 of the bit lines BL and the end 165_E of the bit line hard mask layer 165.

Additionally, in the first periphery connection regions PCR1, both lateral sides and the end of the bit lines BL may be at least partially surrounded by the bit line insulation pattern 173. For example, the end of the bit lines BL may be in direct contact with the bit line insulation pattern 173 and covered by the bit line insulation pattern 173. For example, the end 163_E of the metal layer 163 and the end 165_E of the bit line hard mask layer 165 of the bit lines BL may be at least partially covered by the bit line insulation pattern 173.

The sum of the thickness of the metal layer 163 of the bit lines BL along the third direction Z and the thickness of the bit line hard mask layer 175 along the third direction Z may be substantially equivalent to the thickness of the bit line insulation pattern 173 along the third direction Z.

In the present embodiment, the end 173_E of the bit line insulation pattern 173 and the end SPb_E of the plate part SPb of the shield pattern SP may be positioned in the first periphery connection regions PCR1 and aligned at the substantially same boundary with each other.

Also, in the present embodiment, the sum of the length of bit lines BL along second direction Y and the length of bit line insulation pattern 173 along second direction Y, which at least partially covers the end of the bit lines BL in the first periphery connection regions PCR1, may be substantially equivalent to the length of the plate part SPb of the shield pattern SP along the second direction Y. However, the arrangement relationship between the bit lines BL and the bit line insulation pattern 173, the arrangement relationship between the plate part SPb of the shield pattern SP and the bit line insulation pattern 173, and the relationship of the sum of the length of the bit lines BL and the length of the bit line insulation pattern 173, and the length of the plate part SPb of the shield pattern SP are not necessarily limited thereto and may be changed in various ways.

In the present embodiment, the bit line contact plugs BCNT positioned in the first periphery connection regions PCR1 may overlap the bit line insulation pattern 173 positioned between the adjacent bit lines BL and may overlap the bit line insulation pattern 173 at least partially covering the end of the bit lines BL.

In the case of the semiconductor device according to the present embodiment, as the bit line insulation pattern 173 is positioned between the ends of the adjacent bit lines BL positioned in the first periphery connection region PCR1, the effect may be substantially equivalent to that of the semiconductor device according to the previous embodiment may be achieved.

In addition, as the length of the plate part SPb of the shield pattern SP along the second direction Y is may be longer than the length of the bit lines BL along the second direction Y, the number of the shield pattern contact plugs SCNT connected to the plate part SPb of the shield pattern SP may increase and simultaneously the area of the shield pattern SP may increase, thereby reducing the electrical resistance of the shield pattern SP.

While this disclosure has been described in connection with what is presently considered to be practical embodiments, it is to be understood that the disclosure is not necessarily limited to the disclosed embodiments, but, on the contrary, is intended to cover various modifications and equivalent arrangements included within the spirit and scope of the appended claims.

What is claimed is:

1. A semiconductor device, comprising:
a substrate including a cell array region and a connection region;
bit lines disposed on the substrate and extending along a first direction;
a shield pattern disposed on the bit lines;
word lines spaced apart from each other and disposed on the bit lines along the first direction and extending in a second direction that intersects the first direction; and
active patterns disposed between the word lines on the bit lines,
wherein the shield pattern includes:
line parts disposed between the bit lines and extending along the first direction, and
a plate part disposed on the line parts and extending along the first direction and the second direction,
wherein a length of the line parts along the first direction is different from a length of the plate part along the first direction, and
wherein a length of the bit lines along the first direction is longer than the length of the line parts along the first direction.

2. The semiconductor device of claim 1, further comprising:
a bit line insulation pattern disposed between the bit lines adjacent to each other,
wherein the bit line insulation pattern is in contact with ends of the line parts of the shield pattern.

3. The semiconductor device of claim 2, wherein:
the difference between the length of the bit lines along the first direction and the length of the line parts of the shield pattern along the first direction is substantially the same as the length of the bit line insulation pattern along the first direction.

4. The semiconductor device of claim 2, wherein:
the bit line insulation pattern includes a first bit line insulation pattern and a second bit line insulation pattern sequentially stacked between the bit lines disposed adjacent to each other, and
sides and bottom of the second bit line insulation pattern are at least partially surrounded by the first bit line insulation pattern.

5. The semiconductor device of claim 4, wherein:
the first bit line insulation pattern includes a silicon nitride-based material, and
the second bit line insulation pattern includes a silicon oxide-based material.

6. The semiconductor device of claim 2, wherein:
the length of the plate part of the shield pattern along the first direction is longer than the length of the line parts of the shield pattern along the first direction.

7. The semiconductor device of claim 6, wherein:
the ends of the bit lines are aligned to the substantially same boundary as ends of the plate part of the shield pattern.

8. The semiconductor device of claim 6, wherein:
the length of the bit lines along the first direction is different from the length of the plate part of the shield pattern along the first direction.

9. The semiconductor device of claim 2, wherein:
the connection region includes:
a first periphery connection region disposed adjacent to the cell array region along the first direction, and
a second periphery connection region disposed adjacent to the cell array region and the first periphery connection region along the second direction,
a plurality of bit line contact plugs connected to the bit lines in the first periphery connection region, and
wherein the bit line insulation pattern is disposed in the first periphery connection region.

10. The semiconductor device of claim 9, wherein:
the plurality of bit line contact plugs overlaps the bit lines and the bit line insulation pattern, and
the plurality of bit line contact plugs does not overlap with the line parts of the shield pattern.

11. The semiconductor device of claim 10, wherein:
the ends of the line parts of the shield pattern are disposed in the cell array region, and
an end of the plate part of the shield pattern and an end of the bit lines are disposed in the first periphery connection region.

12. The semiconductor device of claim 1, wherein:
the length of the plate part of the shield pattern along the second direction is different from length of the word lines along the second direction.

13. A semiconductor device, comprising:
a substrate including a cell array region, first periphery connection regions disposed adjacent to the cell array region along a first direction, and second periphery connection regions disposed adjacent to the cell array region and the first periphery connection regions along a second direction intersecting the first direction;
bit lines disposed on the substrate and extending along the first direction;
a shield pattern disposed on the bit lines;
word lines spaced apart from each other and disposed on the bit lines along the first direction and extending along the second direction intersecting the first direction;
active patterns disposed between the word lines;
a back gate electrode disposed between the active patterns and extending along the second direction; and
a bit line insulation pattern disposed between adjacent bit lines in the first periphery connection regions,
wherein the shield pattern includes:
line parts disposed between the bit lines disposed adjacent to each other in the cell array region and extending along the first direction,
a plate part disposed on the line parts and the bit line insulation pattern and extending along the first direction and the second direction,
wherein a length of the line parts along the first direction is shorter than a length of the plate part along the first direction,
wherein a length of the bit lines along the first direction is longer than the length of the line parts along the first direction, and
wherein the end of the plate part of the shield pattern is disposed in the first periphery connection regions.

14. The semiconductor device of claim 13, further comprising:
a plurality of bit line contact plugs connected to the bit lines in the first periphery connection regions,
wherein the plurality of bit line contact plugs overlaps the bit lines and the bit line insulation pattern.

15. The semiconductor device of claim 14, wherein:
the bit line insulation pattern includes a first bit line insulation pattern and a second bit line insulation pattern sequentially stacked between the bit lines disposed adjacent to each other,
sides and bottom of the second bit line insulation pattern are at least partially surrounded by the first bit line insulation pattern, and
the first bit line insulation pattern and the second bit line insulation pattern include different materials.

16. The semiconductor device of claim 14, wherein:
some part of the plurality of bit line contact plugs are connected to the bit lines in the first periphery connection region disposed on one side of the cell array region in the first direction, and
the remaining part of the plurality of bit line contact plugs is connected to the bit lines in the first periphery connection region disposed on the other side of the first direction of the cell array region.

17. The semiconductor device of claim 14, wherein:
the plurality of bit line contact plugs is respectively connected to the plurality of bit lines in the first periphery connection region, which is positioned on one side or the other side of the cell array region among the plurality of first periphery connection regions in the first direction.

18. The semiconductor device of claim 13, wherein:
the length of the bit lines along the first direction is substantially the same as a length of the plate part of the shield pattern along the first direction.

19. The semiconductor device of claim 18, wherein:
the length of the plate part of the shield pattern along the second direction is different from the length of the word lines along the second direction.

20. A semiconductor device, comprising:
a substrate including a cell array region, first periphery connection regions disposed adjacent to the cell array region along a first direction, and second periphery connection regions disposed adjacent to the cell array region and the first periphery connection regions along a second direction intersecting the first direction;
a peripheral circuit structure including peripheral circuits disposed on the substrate and a peripheral circuit insulating layer at least partially covering the peripheral circuits;
bit lines disposed on the substrate and extending along the first direction;
a shield pattern disposed on the bit lines;
word lines spaced apart from each other and on the bit lines along the first direction and extending along the second direction intersecting the first direction;
active patterns disposed between the word lines;
a back gate electrode disposed between the active patterns and extending along the second direction;
a bit line insulation pattern disposed between the bit lines disposed adjacent to each other in the first periphery connection regions; and
a plurality of bit line contact plugs connected to the bit lines disposed in the first periphery connection regions and overlapping the bit lines and the bit line insulation pattern,
wherein the shield pattern includes:
line parts disposed between the bit lines disposed adjacent to each other in the cell array region and extending along the first direction, and
a plate part disposed on the line parts and the bit line insulation pattern and extending along the first direction and the second direction,
wherein a length of the line parts along the first direction is shorter than a length of the plate part along the first direction,
wherein a length of the bit lines along the first direction is longer than the length of the line parts along the first direction, and
wherein the length of the bit lines along the first direction is the substantially same as the length of the plate part along the first direction.
